(19) United States
(12) Patent Application Publication
(10) Pub. No.: US 2026/0124698 A1
(43) Pub. Date: May 7, 2026

(54) LASER PROCESSING APPARATUS, CONTROL METHOD OF LASER PROCESSING APPARATUS, AND ELECTRONIC DEVICE MANUFACTURING METHOD

(71) Applicant: Gigaphoton Inc., Tochigi (JP)

(72) Inventors: Yasufumi KAWASUJI, Oyama-shi (JP); Osamu WAKABAYASHI, Oyama-shi (JP); Akiyoshi SUZUKI, Oyama-shi (JP)

(73) Assignee: Gigaphoton Inc., Tochigi (JP)

(21) Appl. No.: 19/439,268

(22) Filed: Jan. 2, 2026

Related U.S. Application Data
(63) Continuation of application No. PCT/JP2023/031629, filed on Aug. 30, 2023.

(51) Int. Cl. B23K 26/064; G02B 19/00; G02B 27/10; H10W 70/05

(52) U.S. Cl. CPC B23K 26/064; G02B 19/0047; G02B 27/106; G02B 27/1093; H10W 70/095

(57) ABSTRACT

A laser processing apparatus includes a first actuator moving a light shielding plate in a direction perpendicular to an optical axis of a light concentrating optical system, a second actuator capable of generating high density patterns densified by moving a multi-point pattern at a movement pitch shorter than a grid interval of the multi-point pattern, a third actuator moving a workpiece in the direction perpendicular to the optical axis, and a laser processing processor. At each step position in a processing area changed by controlling the third actuator, the laser processing processor selects one of the high density patterns, each having a different number of rows or a different number of columns, and controls the second actuator and the laser device to perform irradiation with the selected pattern, so that drilling is performed on a surface of the workpiece only in the processing area where drilling is required.

### CROSS-REFERENCE TO RELATED APPLICATIONS

The present application is a continuation application of International Application No. PCT/JP2023/031629, filed on Aug. 30, 2023, the entire contents of which are hereby incorporated by reference.

### BACKGROUND

### 1. Technical Field

The present disclosure relates to a laser processing apparatus, a control method of a laser processing apparatus, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as the gas laser device for exposure, a KrF excimer laser device that outputs laser light having a wavelength of about 248.4 nm and an ArF excimer laser device that outputs laser light having a wavelength of about 193.4 nm are used.

Since excimer laser light has a pulse width of about several 10 ns and a wavelength is short, excimer laser light is sometimes used for direct processing of a polymer material, a glass material, or the like.

Chemical bonds in polymeric materials can be broken by excimer laser light having a photon energy higher than the bond energy. Therefore, it is known that non-heating processing of polymeric materials is possible with excimer laser light, and that the processing shape is beautiful.

Further, it is known that, since glass, ceramics, and the like have high absorptance with respect to excimer laser light, even a material that is difficult to be processed with visible and infrared laser light can be processed with excimer laser light.

The KrF excimer laser device and the ArF excimer laser device each have a large spectral line width of about 350 μm to 400 μm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be line-narrowed to the extent that the chromatic aberration can be ignored. For this purpose, there is a case in which a line narrowing module (LNM) including a line narrowing element (etalon, grating, and the like) is provided in a laser resonator of the gas laser device to narrow a spectral line width. In the following, a gas laser device with a narrowed spectral line width is referred to as a line narrowing gas laser device.

### LIST OF DOCUMENTS

### Patent Documents

Patent Document 1: US Patent Application Publication No. 2006/0289412
Patent Document 2: Japanese Patent Application Publication No. 2007-268600
Patent Document 3: Japanese Patent Application Publication No. 2011-161454
Patent Document 4: US Patent Application Publication No. 2003/201578

### SUMMARY

A laser processing apparatus according to an aspect of the present disclosure includes a diffractive optical element configured to divide first laser light output from a laser device into a plurality of beams of second laser light and output the second laser light, a light concentrating optical system configured to generate a grid-like multi-point pattern in which a plurality of light concentration spots are arranged in a row direction and a column direction by concentrating the plurality of beams of second laser light, a light shielding plate capable of shielding at least a part of the multi-point pattern, a first actuator configured to move the light shielding plate in a direction perpendicular to an optical axis of the light concentrating optical system, a second actuator capable of generating high density patterns densified by moving the multi-point pattern at a movement pitch shorter than a grid interval of the multi-point pattern, a third actuator configured to move a workpiece in the direction perpendicular to the optical axis, and a laser processing processor. At each of step positions in a processing area changed by controlling the third actuator, the laser processing processor is configured to select one of the high density patterns being at least four patterns, each having a different number of rows or a different number of columns, and control the second actuator and the laser device to perform irradiation with the selected pattern, so that drilling is performed on a surface of the workpiece only in the processing area where drilling is required.

A control method of a laser processing apparatus according to an aspect of the present disclosure includes, at each of step positions in a processing area changed by controlling a third actuator, selecting one of high density patterns being at least four patterns, each having a different number of rows or a different number of columns, and controlling a second actuator and a laser device to perform irradiation with the selected pattern, so that drilling is performed on a surface of a workpiece only in the processing area where drilling is required. Here, the selecting and the controlling are performed by a laser processing processor. The laser processing apparatus includes a diffractive optical element configured to divide first laser light output from the laser device into a plurality of beams of second laser light and output the second laser light, a light concentrating optical system configured to generate a grid-like multi-point pattern in which a plurality of light concentration spots are arranged in a row direction and a column direction by concentrating the plurality of beams of second laser light, a light shielding plate capable of shielding at least a part of the multi-point pattern, a first actuator configured to move the light shielding plate in a direction perpendicular to an optical axis of the light concentrating optical system, the second actuator capable of generating the high density patterns densified by moving the multi-point pattern at a movement pitch shorter than a grid interval of the multi-point pattern, and the third actuator configured to move the workpiece in the direction perpendicular to the optical axis.

An electronic device manufacturing method according to an aspect of the present disclosure includes forming a plurality of through holes in a glass substrate as a workpiece with a laser processing apparatus; coupling and electrically connecting an interposer and an integrated circuit chip to each other, the interposer including the glass substrate and a conductor arranged in each of the plurality of through holes; and coupling and electrically connecting the interposer and a circuit substrate to each other. Here, the laser processing apparatus includes a diffractive optical element configured to divide first laser light output from a laser device into a plurality of beams of second laser light and output the second laser light, a light concentrating optical system configured to generate a grid-like multi-point pattern in which a plurality of light concentration spots are arranged in a row direction and a column direction by concentrating the plurality of beams of second laser light, a light shielding plate capable of shielding at least a part of the multi-point pattern, a first actuator configured to move the light shielding plate in a direction perpendicular to an optical axis of the light concentrating optical system, a second actuator capable of generating high density patterns densified by moving the multi-point pattern at a movement pitch shorter than a grid interval of the multi-point pattern, a third actuator configured to move a workpiece in the direction perpendicular to the optical axis, and a laser processing processor. At each of step positions in a processing area changed by controlling the third actuator, the laser processing processor is configured to select one of the high density patterns being at least four patterns, each having a different number of rows or a different number of columns, and control the second actuator and the laser device to perform irradiation with the selected pattern, so that drilling is performed on a surface of the workpiece only in the processing area where drilling is required.

### BRIEF DESCRIPTION OF THE DRAWINGS

Embodiments of the present disclosure will be described below merely as examples with reference to the accompanying drawings.

FIG. 1 is a view schematically showing the configuration of a laser processing system 1 according to a comparative example.

FIG. 2 is a view schematically showing the configuration of a laser device 2.

FIG. 3 is a flowchart schematically showing the flow of operation of the laser processing system 1 according to the comparative example.

FIG. 4 is a flowchart showing details of a process of reading processing conditions.

FIG. 5 is a flowchart showing details of a fluence adjustment process.

FIG. 6 is a flowchart showing details of a simultaneous multi-point drilling process.

FIG. 7 is a diagram showing an example of a multi-point pattern MP generated by a DOE 50 and a light concentrating optical system 51.

FIG. 8 is a table showing an example of a first table A.

FIG. 9 is a diagram showing an example of a plurality of step positions of a multi-point pattern MP on a surface 45a of a workpiece 45.

FIG. 10 is a flowchart schematically showing the flow of operation of the laser processing system according to a technique of densification.

FIG. 11 is a flowchart showing details of a high density drilling process.

FIG. 12 is a flowchart showing details of an irradiation process with a high density pattern HP.

FIG. 13 is a diagram showing an example of the high density pattern HP.

FIG. 14 is a table showing an example of a second table B.

FIG. 15 is a diagram showing an example of a plurality of step positions of the high density pattern HP on the surface 45a of the workpiece 45.

FIG. 16 is a view schematically showing the configuration of a laser processing system 1a according to a first embodiment.

FIG. 17 is a flowchart schematically showing the flow of operation of the laser processing system 1a.

FIG. 18 is a flowchart showing details of a process of generating and storing the first table A.

FIG. 19 is a diagram showing an example of a high density pattern HP(1).

FIG. 20 is a diagram showing an example of a high density pattern HP(2).

FIG. 21 is a diagram showing an example of a high density pattern HP(3).

FIG. 22 is a diagram showing an example of a high density pattern HP(4).

FIG. 23 is a diagram showing an example of first to fourth areas R1 to R4.

FIG. 24 is a table showing an example of the first table A.

FIG. 25 is a flowchart showing details of a process of generating and storing a second table B(s).

FIG. 26 is a table showing an example of a second table B(1).

FIG. 27 is a diagram showing an example of the position of a light shielding plate 60 associated with the second table B(1).

FIG. 28 is a table showing an example of a second table B(2).

FIG. 29 is a diagram showing an example of the position of the light shielding plate 60 associated with the second table B(2).

FIG. 30 is a diagram showing an example of the position of the light shielding plate 60 associated with the second table B(2).

FIG. 31 is a table showing an example of a second table B(3).

FIG. 32 is a diagram showing an example of the position of the light shielding plate 60 associated with the second table B(3).

FIG. 33 is a diagram showing an example of the position of the light shielding plate 60 associated with the second table B(3).

FIG. 34 is a table showing an example of a second table B(4).

FIG. 35 is a diagram showing an example of the position of the light shielding plate 60 associated with the second table B(4).

FIG. 36 is a flowchart showing details of the high density drilling process according to the first embodiment.

FIG. 37 is a flowchart showing details of the irradiation process with a high density pattern HP(s) according to the first embodiment.

FIG. 38 is a view schematically showing the configuration of a laser processing system 1b according to a second embodiment.

FIG. 39 is a table showing an example of the second table B(1).

FIG. 40 is a diagram showing an example of the position of the light shielding plate 60 associated with the second table B(1).

FIG. 41 is a table showing an example of the second table B(2).

FIG. 42 is a diagram showing an example of the position of the light shielding plate 60 associated with the second table B(2).

FIG. 43 is a diagram showing an example of the position of the light shielding plate 60 associated with the second table B(2).

FIG. 44 is a table showing an example of the second table B(3).

FIG. 45 is a diagram showing an example of the position of the light shielding plate 60 associated with the second table B(3).

FIG. 46 is a diagram showing an example of the position of the light shielding plate 60 associated with the second table B(3).

FIG. 47 is a table showing an example of the second table B(4).

FIG. 48 is a diagram showing an example of the position of the light shielding plate 60 associated with the second table B(4).

FIG. 49 is a view schematically showing the configuration of a laser processing system 1c according to a third embodiment.

FIG. 50 is a table showing an example of the second table B(1).

FIG. 51 is a diagram showing an example of the position of the light shielding plate 60 associated with the second table B(1).

FIG. 52 is a table showing an example of the second table B(2).

FIG. 53 is a diagram showing an example of the position of the light shielding plate 60 associated with the second table B(2).

FIG. 54 is a table showing an example of the second table B(3).

FIG. 55 is a diagram showing an example of the position of the light shielding plate 60 associated with the second table B(3).

FIG. 56 is a table showing an example of the second table B(4).

FIG. 57 is a diagram showing an example of the position of the light shielding plate 60 associated with the second table B(4).

FIG. 58 is a flowchart showing details of the irradiation process with the high density pattern HP(s) according to the third embodiment.

FIG. 59 is a view schematically showing the configuration of an electronic device 100.

FIG. 60 is a diagram showing a manufacturing method of the electronic device 100.

### DESCRIPTION OF EMBODIMENTS

### <Contents>

1. Description of terms
   1.1 Diffractive optical element
2. Comparative example
   2.1 Configuration
   2.2 Operation
   2.3 Multi-point pattern
   2.4 First table
   2.5 Step position
   2.6 Problem
3. First Embodiment
   3.1 Technique of densification
   3.2 Technique of densification and technique of controlling number of processing holes
      3.2.1 Configuration
      3.2.2 Operation
   3.3 Effect
4. Second Embodiment
   4.1 Configuration
   4.2 Operation
   4.3 Effect
5. Third Embodiment
   5.1 Configuration
   5.2 Operation
   5.3 Effect
6. Electronic device manufacturing method
7. Configuration example of laser processing processor

Hereinafter, embodiments of the present disclosure will be described in detail with reference to the drawings. The embodiments described below shows some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. DESCRIPTION OF TERMS

### 1.1 Diffractive Optical Element

A diffractive optical element (DOE) is an optical element that utilizes diffractive phenomenon of light. For example, a DOE is manufactured by processing a microstructure designed by simulation onto a substrate using microfabrication technology. The DOE can convert laser light into various patterns. In the present disclosure, the laser light is converted into a multi-point pattern MP by the DOE.

### 2. COMPARATIVE EXAMPLE

### 2.1 Configuration

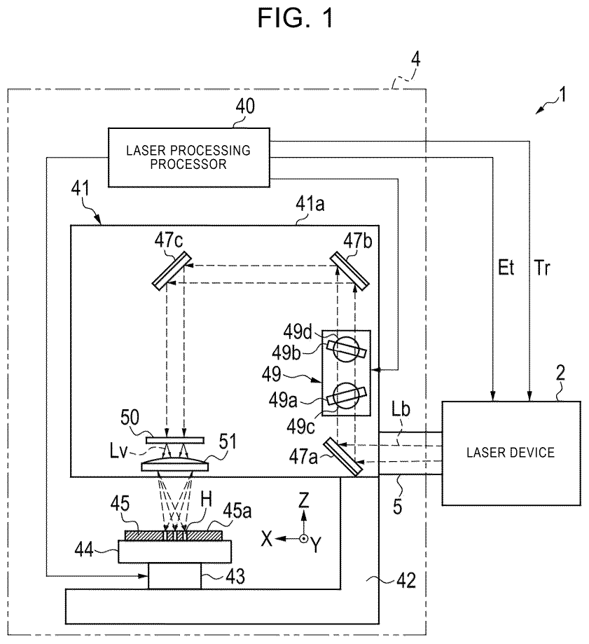

FIG. 1 schematically shows the configuration of a laser processing system 1 according to a comparative example. The comparative example is an example recognized by the applicant as known only by the applicant, and is not a publicly known example admitted by the applicant. The laser processing system 1 includes a laser device 2 and a laser processing apparatus 4 as a main configuration. The laser processing system 1 is used for drilling by which a hole such as a via hole is formed in a glass substrate for an interposer.

The laser device 2 is a laser device that outputs ultraviolet pulse laser light. For example, the laser device 2 is a discharge-excitation-type laser device that outputs ultraviolet pulse laser light using F2, ArF, KrF, XeCl, XeF, or the like as a laser medium. In the present disclosure, the laser device 2 is a KrF excimer laser device that outputs ultraviolet pulse laser light having a center wavelength of 248.4 nm. Hereinafter, the ultraviolet pulse laser light output from the laser device 2 is simply referred to as laser light Lb.

The laser device 2 and the laser processing apparatus 4 are connected by an optical path pipe 5. The optical path pipe 5 is arranged on the optical path of the laser light Lb between the emission port of the laser device 2 and the entrance port of the laser processing apparatus 4. The laser processing apparatus 4 includes a laser processing processor 40, an optical device 41, a frame 42, an XYZ stage 43, and a table 44. The optical device 41 and the XYZ stage 43 are fixed to the frame 42.

The table 44 supports a workpiece 45. The workpiece 45 is a processing target on which drilling is performed. The workpiece 45 is a glass substrate for an interposer, and is, for example, an alkali-free glass substrate. Here, the workpiece 45 may be a substrate formed of quartz glass, an organic material, a silicon single crystal, ceramics, or the like. A plurality of holes H are formed in the workpiece 45 by so-called multi-point drilling.

The XYZ stage 43 supports the table 44. The workpiece 45 is fixed on the table 44. The XYZ stage 43 can move the table 44 in an X direction, a Y direction, and a Z direction, and changes the position of the workpiece 45 by moving the table 44. The X direction, the Y direction, and the Z direction are orthogonal to one another. The X direction and the Y direction are parallel to a surface 45a of the workpiece 45. The Z direction is perpendicular to the surface 45a. The XYZ stage 43 is a movement stage that enables the workpiece 45 to be moved in the direction perpendicular to the optical axis of the light concentrating optical system 51.

The optical device 41 includes a housing 41a, high reflection mirrors 47a, 47b, 47c, an attenuator 49, a DOE 50, and a light concentrating optical system 51. Each configuration member in the optical device 41 is fixed to a holder (not shown), and is arranged at a predetermined position in the housing 41a.

The high reflection mirror 47a is arranged so as to reflect the laser light Lb that has passed through the optical path pipe 5, and to cause the reflected laser light Lb to pass through the attenuator 49 and be incident on the high reflection mirror 47b. The optical path pipe 5 and the housing 41a are purged with, for example, a purge gas. The purge gas is a nitrogen gas, an inert gas, or the like, and is a gas that hardly absorbs the laser light Lb.

The attenuator 49 is arranged on the optical path between the high reflection mirror 47a and the high reflection mirror 47b in the housing 41a. The attenuator 49 includes, for example, two partial reflection mirrors 49a, 49b and rotation stages 49c, 49d for the partial reflection mirrors 49a, 49b. The partial reflection mirrors 49a, 49b are optical elements whose transmittance varies depending on the incident angle of the laser light Lb. The incident angles of the laser light Lb on the partial reflection mirrors 49a, 49b are adjusted by the rotation stages 49c, 49d, respectively.

The high reflection mirrors 47b, 47c are arranged so as to reflect the laser light Lb that has passed through the attenuator 49, and to cause the reflected laser light Lb to be incident on the DOE 50.

The DOE 50 is arranged on the optical path of the laser light Lb reflected by the high reflection mirror 47c. The DOE 50 diffracts the laser light Lb incident from the high reflection mirror 47c, divides the laser light Lb into a plurality of beams of laser light Lv, and outputs the laser light Lv. The DOE 50 divides the laser light Lb in the X direction and the Y direction, thereby converting the laser light into a grid-like multi-point pattern MP. Here, the laser light Lb corresponds to the “first laser light” according to the technology of the present disclosure. The laser light Lv corresponds to the “second laser light” according to the technology of the present disclosure.

The light concentrating optical system 51 is arranged such that the plurality of beams of the laser light Lv output from the DOE 50 enter and the focal plane is located on the surface 45a of the workpiece 45. The light concentrating optical system 51 is, for example, an Fθ lens, concentrates the plurality of beams of the laser light Lv entering from the DOE 50, and generates the multi-point pattern MP in which a plurality of light concentration spots P are arranged in a grid-like manner.

The laser processing processor 40 transmits a target pulse energy Et and a light emission trigger Tr to the laser device 2. The target pulse energy Et is a target value of the pulse energy of the laser light Lb. The light emission trigger Tr is a trigger signal for causing the laser device 2 to output one pulse of the laser light Lb.

The laser processing processor 40 controls the laser device 2 and the XYZ stage 43 so that respective step positions are irradiated with the multi-point pattern MP by a step-and-repeat method with respect to a processing area that requires drilling on the surface 45a of the workpiece 45.

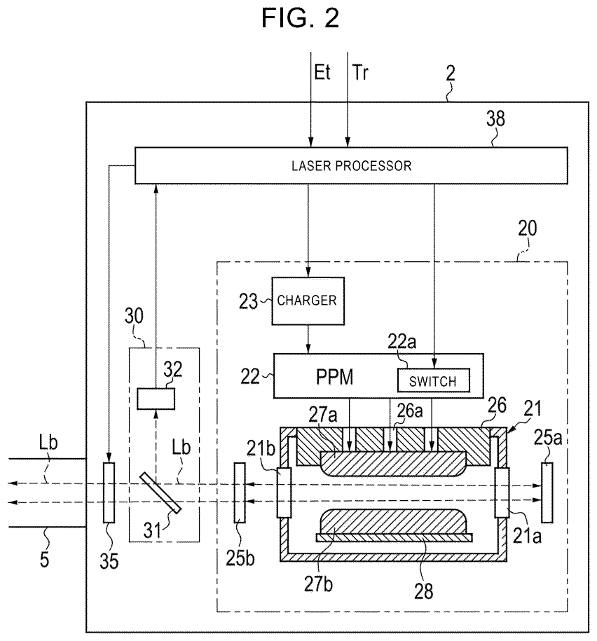

FIG. 2 schematically shows the configuration of the laser device 2. The laser device 2 includes an oscillator 20, a monitor module 30, a shutter 35, and a laser processor 38. The oscillator 20 includes a chamber 21, an optical resonator configured by a rear mirror 25a and an output coupling mirror 25b, a charger 23, and a power supply unit (PPM: Pulsed Power Module) 22.

The chamber 21 is provided with windows 21a, 21b. A laser gas as a laser medium is enclosed in the chamber 21.

Further, an opening is formed in the chamber 21, and an electrically insulating plate 26 in which a plurality of feedthroughs 26a are embedded is provided so as to block the opening. The PPM 22 is arranged on the electrically insulating plate 26. A pair of discharge electrodes 27a, 27b as main electrodes and a ground plate 28 are arranged in the chamber 21. The shape of the discharge surface of the discharge electrodes 27a, 27b is rectangular.

The discharge electrodes 27a, 27b are arranged such that discharge surfaces of the both face each other to excite the laser medium by discharge. The discharge electrode 27a is supported by the electrically insulating plate 26 on a surface opposite to the discharge surface thereof. The discharge electrode 27a is connected to the feedthroughs 26a. The discharge electrode 27b is supported by the ground plate 28 on a surface opposite to the discharge surface thereof.

The PPM 22 includes a switch 22a, a charging capacitor (not shown), a pulse transformer (not shown), a magnetic compression circuit (not shown), and a peaking capacitor (not shown). The peaking capacitor is connected to the feedthroughs 26a via a connection portion (not shown). The charger 23 charges the charging capacitor based on control of the laser processor 38.

The switch 22a is controlled on/off by the laser processor 38. The laser processor 38 turns on the switch 22a in response to the light emission trigger Tr transmitted from the laser processing processor 40.

When the switch 22a is turned on, a current flows from the charging capacitor to the primary side of the pulse transformer, and a current in a reverse direction flows in the secondary side of the pulse transformer by electromagnetic induction. The magnetic compression circuit is connected to the secondary side of the pulse transformer and compresses the pulse width of current pulses. The peaking capacitor is charged by the current pulses. When the voltage of the peaking capacitor reaches a breakdown voltage of the laser gas, breakdown occurs at the laser gas between the discharge electrodes 27a, 27b to cause discharge. One pulse of the laser light Lb is generated by the discharge.

The rear mirror 25a is formed by coating a planar substrate with a high reflection film. The output coupling mirror 25b is formed by coating a planar substrate with a partial reflection film. The chamber 21 is arranged between the rear mirror 25a and the output coupling mirror 25b. The laser light Lb generated in the chamber 21 is amplified by the optical resonator and output from the output coupling mirror 25b.

The monitor module 30 includes a beam splitter 31 and an optical sensor 32. The beam splitter 31 is arranged on the optical path of the laser light Lb output from the output coupling mirror 25b, and reflects a part of the laser light Lb. The optical sensor 32 is arranged at a position where the laser light Lb reflected by the beam splitter 31 enters. The optical sensor 32 measures the pulse energy of the laser light Lb and transmits the measurement value to the laser processor 38.

The laser processor 38 changes the charge voltage of the charger 23 based on the measurement value of the pulse energy by the optical sensor 32 to control the pulse energy of the laser light Lb output from the laser device 2 to be the target pulse energy Et. The shutter 35 is arranged on the optical path of the laser light Lb transmitted through the beam splitter 31. The shutter 35 is opened and closed in response to a command from the laser processor 38. The laser processor 38 controls the shutter 35 to control output of the laser light Lb from the laser device 2.

### 2.2 Operation

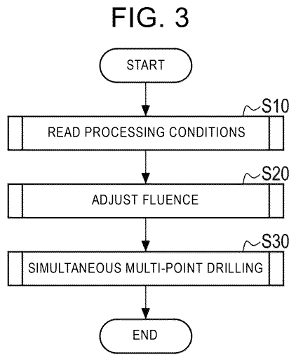

Next, operation of the laser processing system 1 according to the comparative example will be described. FIG. 3 schematically shows the flow of operation of the laser processing system 1 according to the comparative example. Prior to drilling, the workpiece 45 is set on the table 44 of the XYZ stage 43. First, the laser processing processor 40 reads processing conditions (step S10). Next, the laser processing processor 40 adjusts the fluence at the surface 45a of the workpiece 45 (step S20). Then, the laser processing processor 40 controls the laser device 2 and the XYZ stage 43 to perform simultaneous multi-point drilling (step S30). Here, the simultaneous multi-point drilling means processing of simultaneously forming a plurality of holes H in parallel using the laser light Lb output from the laser device 2.

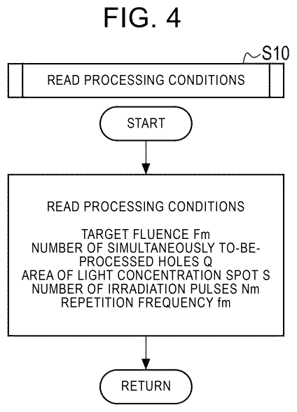

FIG. 4 shows details of a process of reading the processing conditions (step S10). The processing conditions read by the laser processing processor 40 in step S10 include, for example, a target fluence Fm, a number of simultaneously to-be-processed holes Q, an area S of the light concentration spot P, a number of irradiation pulses Nm, and a repetition frequency fm. The processing conditions may be read from an external device (not shown), via a network, or from an input device operated by an operator.

The target fluence Fm is the pulse energy density per pulse of one light concentration spot P on the surface 45a of the workpiece 45, and is a value greater than a processing threshold of the workpiece 45. When the workpiece 45 is an alkali-free glass substrate, the target fluence Fm is several tens J/cm².

The number of simultaneously to-be-processed holes Q is the number of holes H to be simultaneously processed, and corresponds to the number of the beams of the laser light Lv generated by the DOE 50, that is, the number of light concentration spots P included in the multi-point pattern MP described above. The area S of one light concentration spot P is calculated by a relational expression S=π(D/2)², for example, where D is the diameter of the distribution of the light intensity that is 1/e2 times or more of the peak intensity.

The number of irradiation pulses Nm is the number of pulses of the laser light Lb required to form a through hole that penetrates the workpiece 45 or a non-through hole having a target depth as the hole H. The repetition frequency fm is a repetition frequency of the laser light Lb output from the laser device 2, and is, for example, a rated value. The repetition frequency fm is, for example, 4 to 6 kHz.

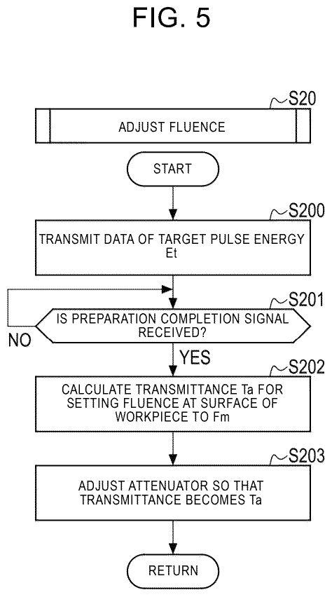

FIG. 5 shows details of a fluence adjustment process (step S20). In step S20, first, the laser processing processor 40 transmits data of the target pulse energy Et required for drilling to the laser device 2 (step S200). After receiving the data, the laser device 2 controls the oscillator 20, and transmits a preparation completion signal to the laser processing processor 40 when becoming capable of outputting the laser light Lb having the target pulse energy Et.

Next, the laser processing processor 40 determines whether or not a preparation completion signal is received from the laser device 2 (step S201). Upon determining that the preparation completion signal has been received (step S201: YES), the laser processing processor 40 calculates a transmittance Ta of the attenuator 49 for setting the fluence at the surface 45a of the workpiece 45 to the target fluence Fm (step S202). For example, the laser processing processor 40 calculates the transmittance Ta using the following Expression (1). Here, To is the transmittance of the optical device 41 when the transmittance of the attenuator 49 is 100%.

Ta=Fm×Q×S/(Et×T₀) (1)

Next, the laser processing processor 40 adjusts the attenuator 49 so that the transmittance becomes Ta (step S203). Specifically, the laser processing processor 40 controls the incident angles on the partial reflection mirrors 49a, 49b by controlling the rotation stages 49c, 49d, respectively, so that the transmittance of the attenuator 49 becomes Ta.

The laser processing processor 40 may adjust the target pulse energy Et in place of the transmittance of the attenuator 49 or in addition to the transmittance of the attenuator 49 so that the fluence at the surface 45a of the workpiece 45 becomes the target fluence Fm.

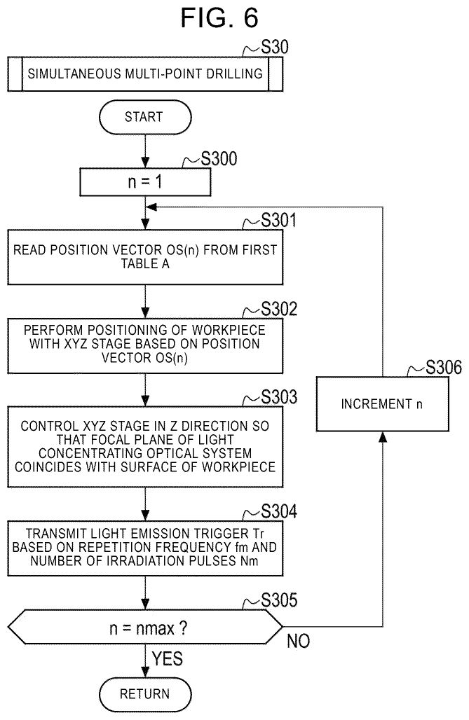

FIG. 6 shows details of the simultaneous multi-point drilling process (step S30). In step S30, first, the laser processing processor 40 sets a parameter n indicating a step position on the surface 45a of the workpiece 45 to 1 (step S300). Next, the laser processing processor 40 reads a position vector OS(n) from a first table A (step S301). The position vector OS(n) indicates the coordinates of the n-th step position.

Next, the laser processing processor 40 controls the XYZ stage 43 based on the position vector OS(n) to perform positioning of the workpiece 45 in the X direction and the Y direction (step S302). Further, the laser processing processor 40 controls the XYZ stage 43 in the Z direction so that the focal plane of the light concentrating optical system 51 coincides with the surface 45a of the workpiece 45 (step S303).

Next, the laser processing processor 40 transmits the light emission trigger Tr to the laser device 2 based on the repetition frequency fm and the number of irradiation pulses Nm (step S304). Consequently, the laser light Lb is output from the laser device 2 in synchronization with the light emission trigger Tr, and enters the laser processing apparatus 4 via the optical path pipe 5. The laser light Lb is reflected by the high reflection mirror 47a, attenuated by the attenuator 49, and then reflected by the high reflection mirrors 47b, 47c. The laser light Lb reflected by the high reflection mirror 47c is incident on the DOE 50. The DOE 50 divides the laser light Lb into a plurality of beams of the laser light Lv, and outputs the laser light Lv. The light concentrating optical system 51 concentrates the plurality of beams of the laser light Lv and forms the multi-point pattern MP on the surface 45a of the workpiece 45. Thus, a hole His formed by laser ablation at a position corresponding to each light concentration spot P included in the multi-point pattern MP.

Next, the laser processing processor 40 determines whether or not the currently set parameter n is a maximum value nmax, that is, whether or not the current step position is the final step position (step S305). When the parameter n is determined not to be the maximum value nmax (step S305: NO), the laser processing processor 40 increments the parameter n, that is, adds 1 to the parameter n (step S306), and returns processing to step S301.

The laser processing processor 40 repeatedly executes steps S301 to S306 until the parameter n reaches the maximum value nmax. When the parameter n is determined to be the maximum value nmax (step S305: YES), the laser processing processor 40 ends the simultaneous multi-point drilling process.

### 2.3 Multi-Point Pattern

In the present disclosure, the arrangement of points in the X direction is defined as a “column”, and the arrangement of points in the Y direction is defined as a “row”. The number of rows aligned in the X direction is referred to as “number of rows”, and the number of columns aligned in the Y direction is referred to as “number of columns”. Here, a point refers to the hole H or a light concentration spot P. In the following, the X direction may be referred to as a “column direction”, and the Y direction may be referred to as a “row direction”.

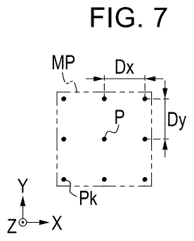

FIG. 7 shows an example of the multi-point pattern MP generated by the DOE 50 and the light concentrating optical system 51. The multi-point pattern MP is a pattern having a rectangular outer shape in which a plurality of light concentration spots P are arranged in a grid-like manner in the row direction and the column direction. In the comparative example, let the number of rows of the light concentration spots P included in the multi-point pattern MP be 3 and the number of columns thereof be 3. Here, an interval Dx of the multi-point pattern MP in the X direction and an interval Dy thereof in the Y direction may be the same or different. The interval Dx and the interval Dy correspond to the “grid interval” according to technology of the present disclosure.

Further, one of the plurality of light concentration spots P included in the multi-point pattern MP is referred to as a reference spot Pk. In the comparative example, one of the light concentration spots P located at the four corners of the multi-point pattern MP is set as the reference spot Pk.

### 2.4 First Table

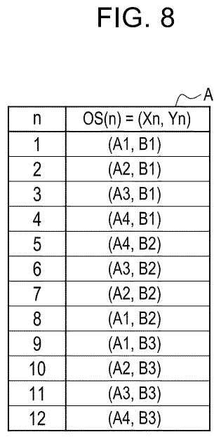

FIG. 8 shows an example of the first table A. In the first table A, the parameter n and the position vector OS(n) are associated with each other. For example, the first table A is a data table stored in the memory of the laser processing processor 40. The position vector OS(n) represents the position of the reference spot Pk. Specifically, the position vector OS(n) is represented by an X coordinate Xn and a Y coordinate Yn of the reference spot Pk. In the comparative example, nmax=12.

### 2.5 Step Position

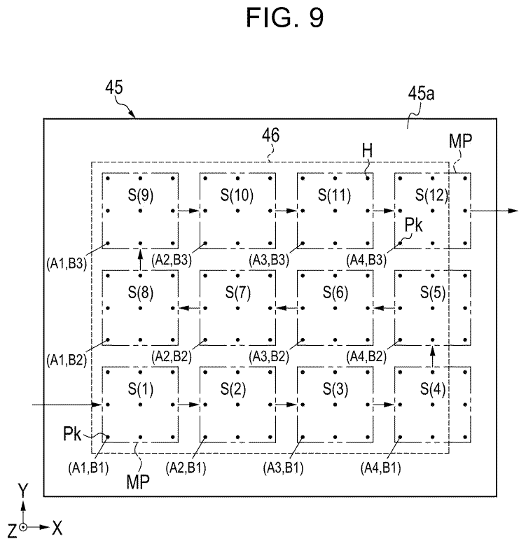

FIG. 9 shows an example of a plurality of step positions of the multi-point pattern MP on the surface 45a of the workpiece 45. S(n) indicates the n-th step position of the multi-point pattern MP. At the time of the simultaneous multi-point drilling, the laser processing processor 40 controls the XYZ stage 43 to move the workpiece 45 so that irradiation with the multi-point pattern MP is sequentially performed at each step position S(n). Arrows shown in FIG. 9 indicate a movement path of the step positions S(n) at which irradiation with the multi-point pattern MP is performed. The step position S(n) is defined by the position of the reference spot Pk, that is, the position vector OS(n).

### 2.6 Problem

Next, a problem of the laser processing apparatus 4 according to the comparative example will be described. As shown in FIG. 9, by performing irradiation with the multi-point pattern MP while changing the step position S(n), a large number of holes H can be processed on the surface 45a of the workpiece 45.

In recent years, it has been desired to perform drilling at higher density. To perform drilling at high density, it is conceivable to shorten the interval Dx and the interval Dy of the multi-point pattern MP. Here, to shorten the interval Dx and interval Dy, it is required to reduce the diffraction angle of the laser light Lb by the DOE 50. However, when the diffraction angle is reduced, the structure of the DOE 50 becomes rough and the laser light Lb becomes less likely to be diffracted. For this reason, it is desired to enable drilling to be performed at higher density without shortening the interval Dx and the interval Dy of the multi-point pattern MP.

Further, in FIG. 9, the reference numeral 46 denotes an example of a processing area that requires drilling on the surface 45a of the workpiece 45. The processing area 46 is a rectangular area in which the holes H arranged in a grid-like manner are to be formed. When the number of rows and the number of columns of the processing area 46 are not divisible by the number of rows and the number of columns of the multi-point pattern MP, respectively, unnecessary holes H are formed outside the processing area 46. In the example shown in FIG. 9, since the number of rows of the holes H included in the processing area 46 is not divisible by the number of rows of the multi-point pattern MP, unnecessary holes H corresponding to one row are formed outside the processing area 46. Therefore, it is desired to enable drilling to be performed only in the processing area 46.

The present disclosure provides a laser processing apparatus, a control method of a laser processing apparatus, and an electronic device manufacturing method, enabling drilling to be performed only in the processing area 46 at higher density.

### 3. FIRST EMBODIMENT

A laser processing system 1a according to a first embodiment of the present disclosure will be described. Any component same as that described above is denoted by an identical reference sign, and duplicate description thereof is omitted unless specific description is needed.

### 3.1 Technique of Densification

First, description will be provided on a technique of densification that enables drilling to be performed at higher density. The configuration of the laser processing system according to the technique of densification is similar to the configuration of the laser processing system 1 according to the comparative example.

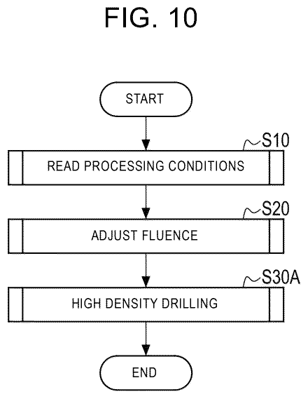

FIG. 10 schematically shows the flow of operation of the laser processing system according to a technique of densification. The operation of the laser processing system according to the technique of densification is similar to the flow of the operation of the laser processing system 1 according to the comparative example, except that the high density drilling process is executed (step S30A) instead of the simultaneous multi-point drilling process (step S30).

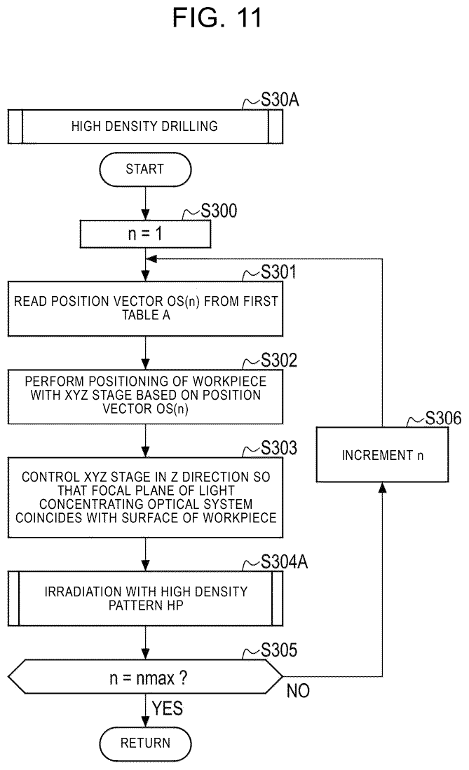

FIG. 11 shows details of the high density drilling process (step S30A). The high density drilling process is similar to the simultaneous multi-point drilling process according to the comparative example except that the irradiation process (step S304A) with a high density pattern HP is executed instead of step S304 of the comparative example. As will be described later in detail, the high density pattern HP is a pattern in which the light concentration spots P are densified by moving the multi-point pattern MP at a moving pitch shorter than the grid interval.

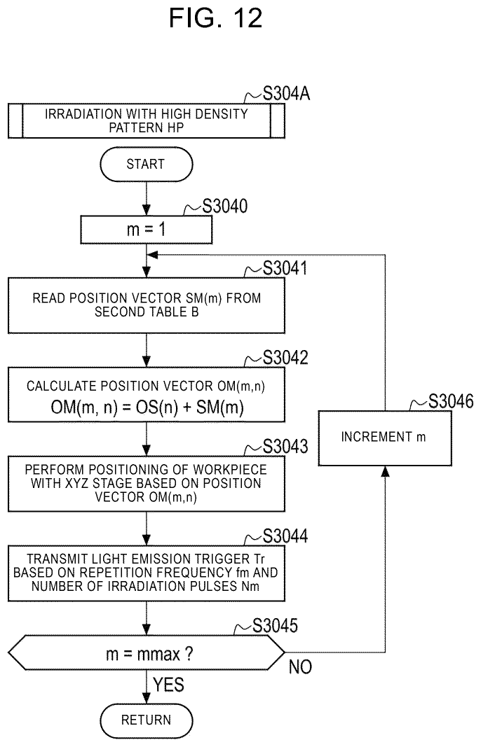

FIG. 12 shows details of the irradiation process with the high density pattern HP (step S304A). In step S304A, first, the laser processing processor 40 sets a parameter m indicating the position of the reference spot Pk to 1 (step S3040). Next, the laser processing processor 40 reads a movement vector SM(m) from a second table B (step S3041). The movement vector SM(m) indicates a movement amount and a movement direction from the position of the first reference spot Pk to the position of the m-th reference spot Pk. The position of the first reference spot Pk is the position of the reference spot Pk when densification of the light concentration spots P is not performed as in the comparative example.

Next, the laser processing processor 40 calculates the position vector OM(m,n) based on Expression (2) below (step S3042). The position vector OM(m,n) indicates the position of the m-th reference-spot Pk at the step position S(n).

OM(m,n)=OS(n)+SM(m) (2)

Next, the laser processing processor 40 controls the XYZ stage 43 based on the position vector OM(m,n) to perform positioning of the workpiece 45 in the X direction and the Y direction (step S3043). Next, the laser processing processor 40 transmits the light emission trigger Tr to the laser device 2 based on the repetition frequency fm and the number of irradiation pulses Nm (step S3044). Thus, a hole H is formed by laser ablation at a position corresponding to each light concentration spot included in the workpiece 45.

Next, the laser processing processor 40 determines whether or not the currently set parameter m is a maximum value mmax, that is, whether or not the current reference spot Pk is the final position (step S3045). When the parameter m is determined not to be the maximum value mmax (step S3045: NO), the laser processing processor 40 increments the parameter m (step S3046), and returns processing to step S3041.

The laser processing processor 40 repeatedly executes steps S3041 to S3046 until the parameter m reaches the maximum value mmax. When the parameter m is determined to be the maximum value mmax (step S3045: YES), the laser processing processor 40 ends the irradiation process with the high density pattern HP.

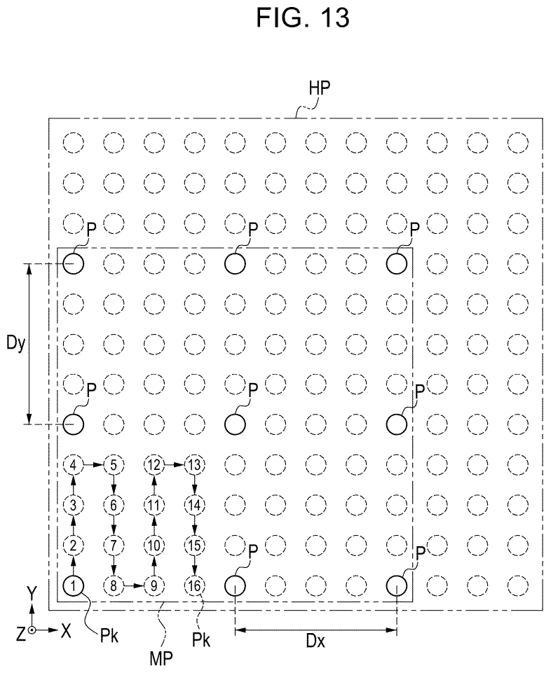

FIG. 13 shows an example of the high density pattern HP. The high density pattern HP is generated by performing irradiation with the multi-point pattern MP while moving the workpiece 45 in the X direction and the Y direction at a shorter movement pitch than the interval Dx and the interval Dy by the XYZ stage 43. The numbers shown in FIG. 13 indicate the parameter m, and the arrows indicate the movement order of the reference spot Pk.

The movement pitch of the reference spot Pk in the X direction is a value obtained by dividing the interval Dx by a positive integer. In the example shown in FIG. 13, the movement pitch of the reference spot Pk in the X direction is a value obtained by dividing the interval Dx by 4. The movement pitch of the reference spot Pk in the Y direction is a value obtained by dividing the interval Dy by a positive integer. In the example shown in FIG. 13, the movement pitch of the reference spot Pk in the Y direction is a value obtained by dividing the interval Dy by 4. Thus, the high density pattern HP is a pattern in which a plurality of light concentration spots P are arranged in a grid-like manner.

In the example shown in FIG. 13, mmax=16. The movement order of the reference spot Pk is determined such that the total movement length of the reference spot Pk for generating the high density pattern HP is the shortest.

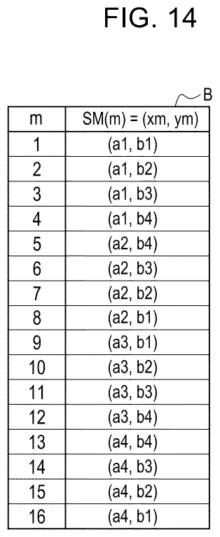

FIG. 14 shows an example of the second table B. In the second table B shown in FIG. 14, the relationship between the parameter m and the movement vector SM(m) is defined. The movement vector SM(m) is represented by a movement amount xm in the X direction and a movement amount ym in the Y direction. In the example shown in FIGS. 13 and 14, a1=0 and b1=0.

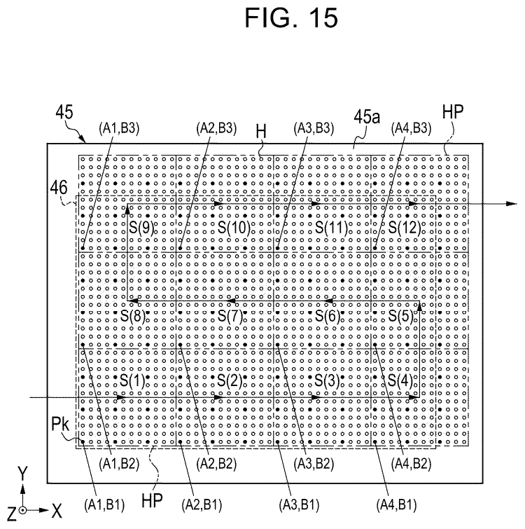

FIG. 15 shows an example of the plurality of step positions S(n) of the high density pattern HP on the surface 45a of the workpiece 45. The step position S(n) of the high density pattern HP is defined by the position of the reference spot Pk at m=1. That is, the step position S(n) of the high density pattern HP is represented by the position vector OS(n) described in the comparative example.

As shown in FIG. 15, the first table A stores the position vector OS(n) determined so that the plurality of light concentration spots P are arranged in a grid-like manner by the plurality of high density patterns HP. The step position S(n) of the high density pattern HP may be the same as the step position S(n) of the multi-point pattern MP described in the comparative example.

As described above, by performing irradiation with the multi-point pattern MP while the workpiece 45 is finely moved, it is possible to irradiate each of the step positions S(n) with the high density pattern HP. However, as in the comparative example, an unnecessary hole H may be formed outside the processing area 46.

### 3.2 Technique of Densification and Technique of Controlling Number of Processing Holes

Next, the first embodiment according to a technique that allows drilling only in the processing area 46 at higher density will be described.

### 3.2.1 Configuration

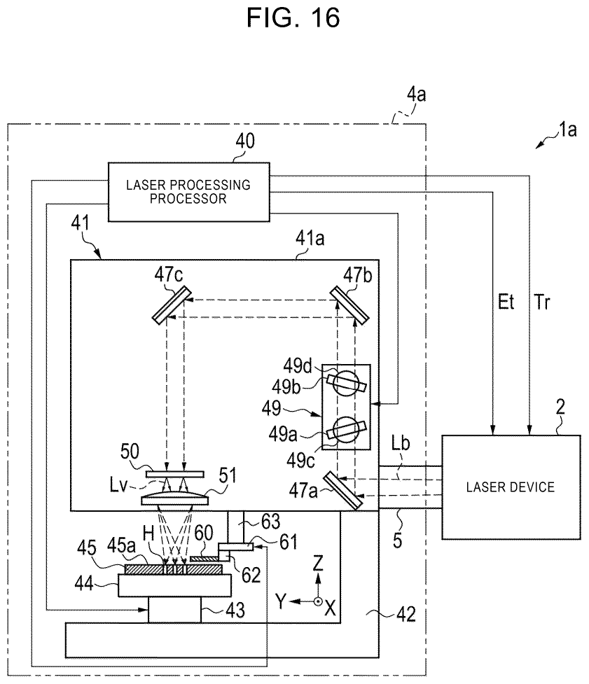

FIG. 16 schematically shows the configuration of the laser processing system 1a according to the first embodiment. The laser processing system 1a differs from the laser processing system 1 according to the comparative embodiment only in the configuration of a laser processing apparatus 4a. The laser processing apparatus 4a includes a light shielding plate 60 and an XY stage 61 in addition to the configuration of the laser processing apparatus 4 according to the comparative example.

The light shielding plate 60 is arranged in the vicinity of the surface 45a of the workpiece 45. The light shielding plate 60 is held by a holder 62 that is movable in the X direction and the Y direction on the XY stage 61. The XY stage 61 is fixed to the housing 41a via a bracket 63.

The XY stage 61 is a two-axis movement stage that moves the light shielding plate 60 in a direction perpendicular to the optical axis of the light concentrating optical system 51. Specifically, the XY stage 61 moves the light shielding plate 60 in the X direction and the Y direction via the holder 62. The XY stage 61 is controlled by the laser processing processor 40. The laser processing processor 40 changes the relative position of the light shielding plate 60 with respect to the multi-point pattern MP by controlling the XY stage 61. The XY stage 61 is an example of the “first actuator” according to the technology of the present disclosure.

The light shielding plate 60 is formed of a material that is not easily drilled by the light concentration spot P to be capable of shielding at least a part of the multi-point pattern MP. The light shielding plate 60 is made of metal such as W, Ta, Mo or the like having high melting point, ceramics such as SiC, ZrO₂, BN or the like, silicon, diamond or the like having a higher processing threshold than glass.

The light shielding plate 60 has, for example, an L-shape including a side parallel to the X direction and a side parallel to the Y direction, and is configured to be capable of shielding at least one row and at least one column of the light concentration spots P included in the multi-point pattern MP.

In the present embodiment, the workpiece 45 is finely moved by the XYZ stage 43 in a step-and-repeat method while a part of the multi-point pattern MP is shielded by the light shielding plate 60, to generate the high density pattern HP(s). Here, the parameter s represents the type of the high density pattern HP(s). In the present embodiment, the parameter s is an integer from 1 to 4. The high density patterns HP(1) to HP(4) each have a different number of rows or a different number of columns of the light concentration spots P so that drilling is performed only in the processing area 46. The number of the high density pattern HP(s) may be 4 or more. That is, the parameter s may be an integer equal to or more than 4. Further, in the present embodiment, the XYZ stage 43 corresponds to the “second actuator and third actuator” according to the technology of the present disclosure.

### 3.2.2 Operation

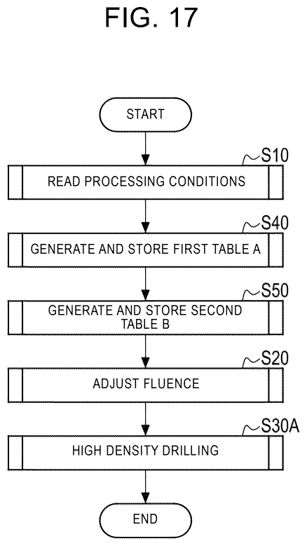

Next, operation of the laser processing system 1a according to the first embodiment will be described. FIG. 17 schematically shows the flow of operation of the laser processing system 1a. In the present embodiment, step S40 and step S50 are added between step S10 and step S20.

After reading the processing conditions in step S10, the laser processing processor 40 generates and stores the first table A (step S40), and generates and stores the second table B (step S50). The laser processing processor 40 then adjusts the fluence (step S20) and performs high density drilling (step S30A).

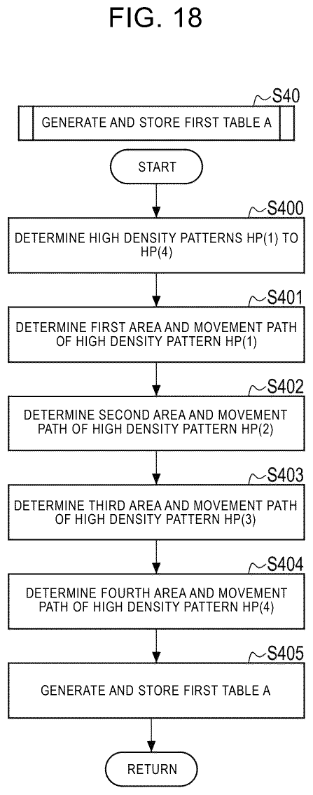

FIG. 18 shows details of a process of generating and storing the first table A (step S40). In step S40, first, the laser processing processor 40 determines the high density patterns HP(1) to HP(4) (step S400). For example, the laser processing processor 40 determines the high density patterns HP(1) to HP(4) based on drilling information including the number of rows and the number of columns of the holes H that are required to be formed in the processing area 46. The drilling information may be read from an external device (not shown), via a network, or from an input device operated by an operator.

In the following steps, the first to fourth areas R1 to R4 to be irradiated with the high density patterns HP(1) to HP(4) are respectively determined so that drilling is performed only in the processing area 46. The high density patterns HP(1) to HP(4) are an example of “at least four high density patterns” according to the technology of the present disclosure. The first to fourth areas R1 to R4 are an example of “at least four areas” according to the technology of the present disclosure.

The laser processing processor 40 determines the first area R1 at which irradiation with one or more high density patterns HP(1) is performed and the movement path of the high density patterns HP(1) in the first area R1 (step S401). Next, the laser processing processor 40 determines the second area R2 at which irradiation with one or more high density patterns HP(2) is performed and the movement path of the high density patterns HP(2) in the second area R2.

Next, the laser processing processor 40 determines the third area R3 at which irradiation with one or more high density patterns HP(3) is performed and the movement path of the high density patterns HP(3) in the third area R3 (step S403). Next, the laser processing processor 40 determines the fourth area R4 at which irradiation with one or more high density patterns HP(4) is performed and the movement path of the high density patterns HP(4) in the fourth area R4 (step S404).

Then, the laser processing processor 40 generates the first table A based on the information determined in steps S400 to S404 and stores the first table A in the memory (step S405).

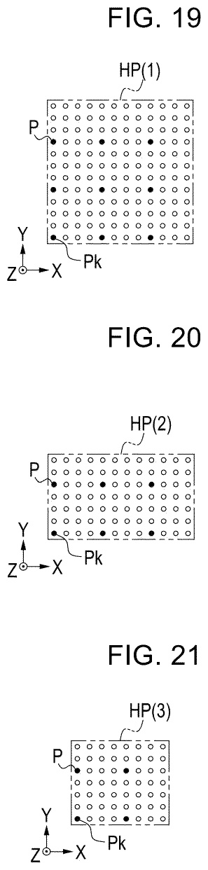

FIG. 19 shows an example of the high density pattern HP(1). The high density pattern HP(1) is generated by not shielding the multi-point pattern MP with the light shielding plate 60. That is, the high density pattern HP(1) is the same as the high density pattern HP shown in FIG. 13.

FIG. 20 shows an example of the high density pattern HP(2). The high density pattern HP(2) is generated by shielding one or more rows of the multi-point pattern MP with the light shielding plate 60.

FIG. 21 shows an example of the high density pattern HP(3). The high density pattern HP(3) is generated by shielding one or more rows and one or more columns of the multi-point pattern MP with the light shielding plate 60.

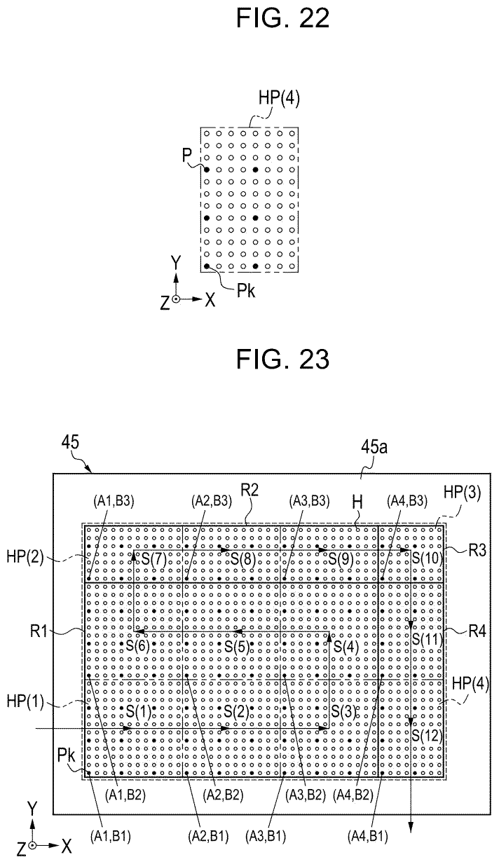

FIG. 22 shows an example of the high density pattern HP(4). The high density pattern HP(4) is generated by shielding one or more columns of the multi-point pattern MP with the light shielding plate 60.

The laser processing processor 40 can select one of the high density patterns HP(1) to HP(4) by controlling the XY stage 61 that moves the light shielding plate 60.

FIG. 23 shows an example of the first to fourth areas R1 to R4. The processing area 46 is divided into the first to fourth areas R1 to R4. In the example shown in FIG. 23, the first area R1 is an area configured of six high density patterns HP(1). The second area R2 is an area configured of three high density patterns HP(2). The third area R3 is an area configured of one high density pattern HP(3). The fourth area R4 is an area configured of two high density patterns HP(4). In the present embodiment, each of the first to fourth areas R1 to R4 is a single block area that is not divided into plural areas.

In FIG. 23, the movement path of the high density patterns HP(1) to HP(4) is indicated by arrows. The movement path is a continuous path in which the step position S(n) of the irradiation target is changed to an adjacent step position S(n+1).

The number of rows of the high density pattern HP(2) is equal to the remainder obtained by dividing the number of rows of the holes H to be processed in the processing area 46 by the number of rows of the high density pattern HP(1). The number of columns of the high density pattern HP(2) is equal to the number of columns of the high density pattern HP(1).

The number of rows of the high density pattern HP(3) is equal to the remainder obtained by dividing the number of rows of the holes H to be processed in the processing area 46 by the number of rows of the high density pattern HP(1). The number of columns of the high density pattern HP(3) is equal to the remainder obtained by dividing the number of columns of the holes H to be processed in the processing area 46 by the number of columns of the high density pattern HP(1).

The number of rows of the high density pattern HP(4) is equal to the number of rows of the high density pattern HP(1). The number of columns of the high density pattern HP(4) is equal to the remainder obtained by dividing the number of columns of the holes H to be processed in the processing area 46 by the number of columns of the high density pattern HP(1).

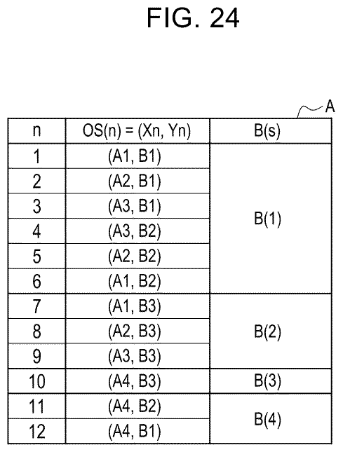

FIG. 24 shows an example of the first table A. The parameter n and the position vector OS(n) are associated with each other. In the first table A, the position vector OS(n) is determined based on the movement path. In the first table A, the parameter n and the second table B(s) are associated with each other. The second table B(s) is a data table for generating the high density pattern HP(s).

The second table B(1) is associated with the step positions S(n) of 1≤n≤6 included in the first area R1. The second table B(2) is associated with the step positions S(n) of 7≤n≤9 included in the second area R2. The second table B(3) is associated with the step position S(n) of n=10 included in the third area R3. The second table B(4) is associated with the step positions S(n) of 11≤n≤12 included in the fourth area R4.

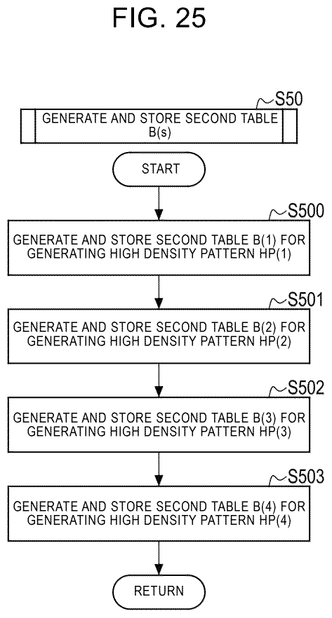

FIG. 25 shows details of a process of generating and storing the second table B(s) (step S50). In step S50, first, the laser processing processor 40 generates the second table B(1) for generating the high density pattern HP(1) and stores the second table B(1) in the memory (step S500). Next, the laser processing processor 40 generates the second table B(2) for generating the high density pattern HP(2) and stores the second table B(2) in the memory (step S501).

Next, the laser processing processor 40 generates the second table B(3) for generating the high density pattern HP(3) and stores the second table B(3) in the memory (step S502). Next, the laser processing processor 40 generates the second table B(4) for generating the high density pattern HP(4) and stores the second table B(4) in the memory (step S503).

In the second table B(s), the movement vector SM(m) and the position vector OB(m) indicating the position of the light shielding plate 60 are associated with the parameter m. For example, the position vector OB(m) is represented by an X coordinate Bxm and a Y coordinate Bym of a corner portion of the light shielding plate 60. The position vector OB(m) is an example of the “control value of the first actuator” according to the technology of the present disclosure. The movement vector SM(m) is an example of the “control value of the second actuator” according to the technology of the present disclosure. Accordingly, the second table B(s) is an example of the “data table in which the control value of the first actuator and the control value of the second actuator are defined” according to the technology of the present disclosure.

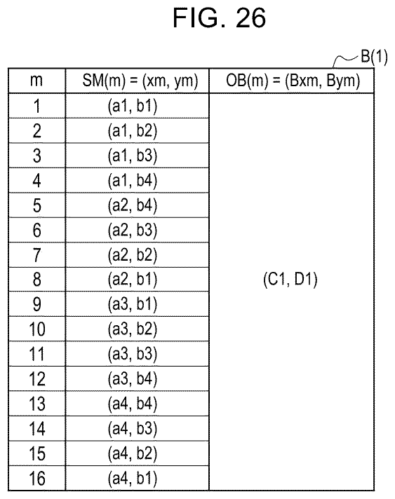

FIG. 26 shows an example of the second table B(1). In the second table B(1), in addition to the movement vector SM(m), the position vector OB(m) indicating the position of the light shielding plate 60 for generating the high density pattern HP(1) is associated with the parameter m. In the second table B(1), one position vector OB(m)=(C1,D1) is associated with 1≤m≤16.

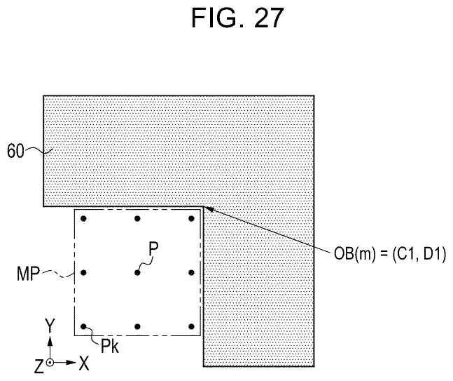

FIG. 27 shows an example of the position of the light shielding plate 60 associated with the second table B(1). In the example shown in FIG. 27, the light shielding plate 60 is located at a position where the multi-point pattern MP is not shielded.

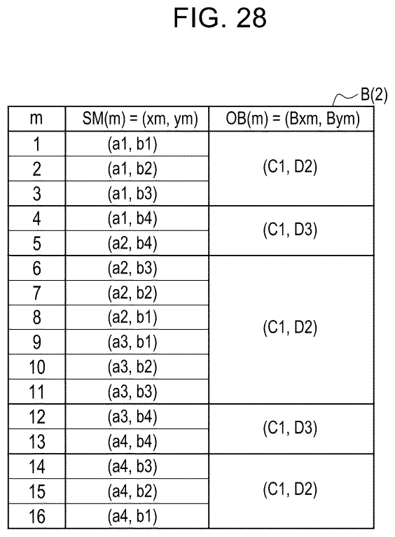

FIG. 28 shows an example of the second table B(2). In the second table B(2), in addition to the movement vector SM(m), the position vector OB(m) indicating the position of the light shielding plate 60 for generating the high density pattern HP(2) is associated with the parameter m. In the second table B(2), the position vector OB(m)=(C1,D2) is associated with 1≤m≤3, 6≤m≤11, and 14≤m≤16. Further, the position vector OB(m)=(C1,D3) is associated with 4≤m≤5 and 12≤m≤13.

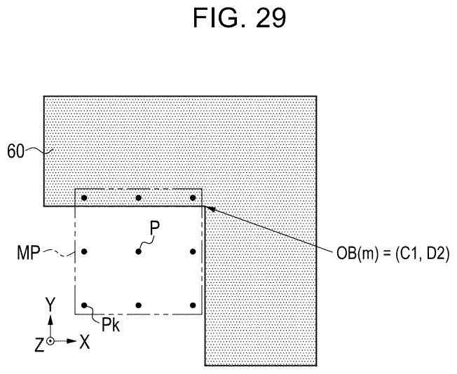

FIG. 29 shows an example of the position of the light shielding plate 60 associated with the second table B(2). In the example shown in FIG. 29, the light shielding plate 60 is located to shield one row of the multi-point pattern MP based on the position vector OB(m)=(C1,D2).

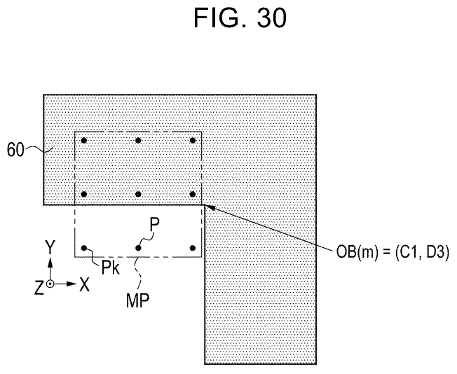

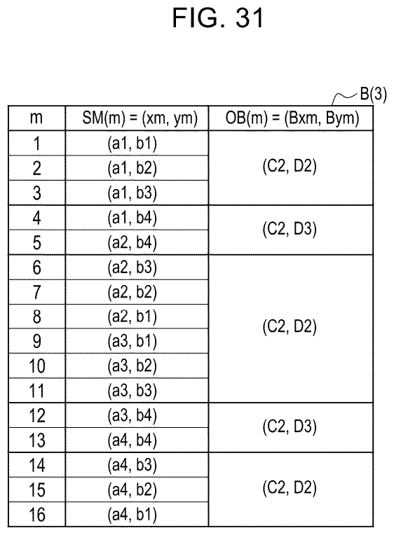

FIG. 30 shows an example of the position of the light shielding plate 60 associated with the second table B(2). In the example shown in FIG. 30, the light shielding plate 60 is located to shield two rows of the multi-point pattern MP based on the position vector OB(m)=(C1,D3).

FIG. 31 shows an example of the second table B(3). In the second table B(3), in addition to the movement vector SM(m), the position vector OB(m) indicating the position of the light shielding plate 60 for generating the high density pattern HP(3) is associated with the parameter m. In the second table B(3), the position vector OB(m)=(C2,D2) is associated with 1≤m≤3, 6≤m≤11, and 14≤m≤16. Further, the position vector OB(m)=(C2,D3) is associated with 4≤m≤5 and 12≤m≤13.

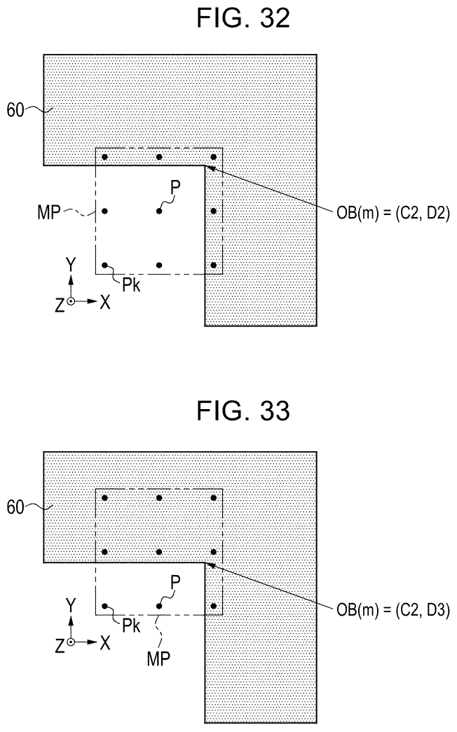

FIG. 32 shows an example of the position of the light shielding plate 60 associated with the second table B(3). In the example shown in FIG. 32, the light shielding plate 60 is located to shield one row and one column of the multi-point pattern MP based on the position vector OB(m)=(C2,D2).

FIG. 33 shows an example of the position of the light shielding plate 60 associated with the second table B(3). In the example shown in FIG. 33, the light shielding plate 60 is located to shield two rows and one column of the multi-point pattern MP based on the position vector OB(m)=(C2, D3).

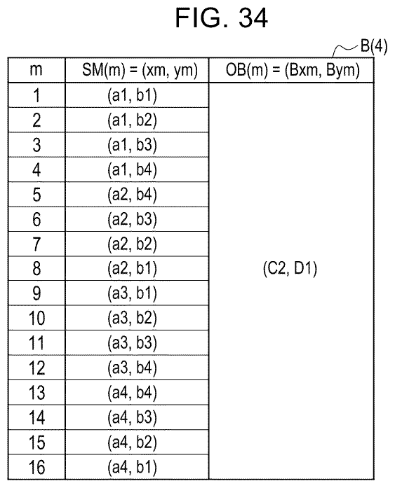

FIG. 34 shows an example of the second table B(4). In the second table B(4), in addition to the movement vector SM(m), the position vector OB(m) indicating the position of the light shielding plate 60 for generating the high density pattern HP(4) is associated with the parameter m. In the second table B(1), the position vector OB(m)=(C2,D1) is associated with 1≤m≤16.

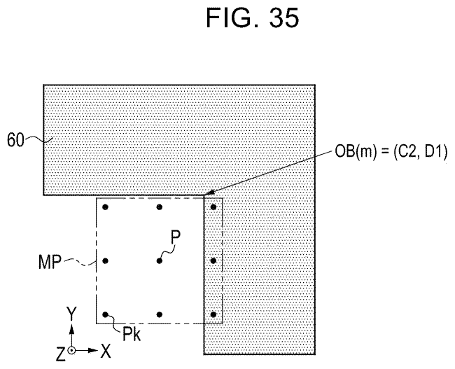

FIG. 35 shows an example of the position of the light shielding plate 60 associated with the second table B(4). In the example shown in FIG. 35, the light shielding plate 60 is located to shield one column of the multi-point pattern MP based on the position vector OB(m)=(C2,D1).

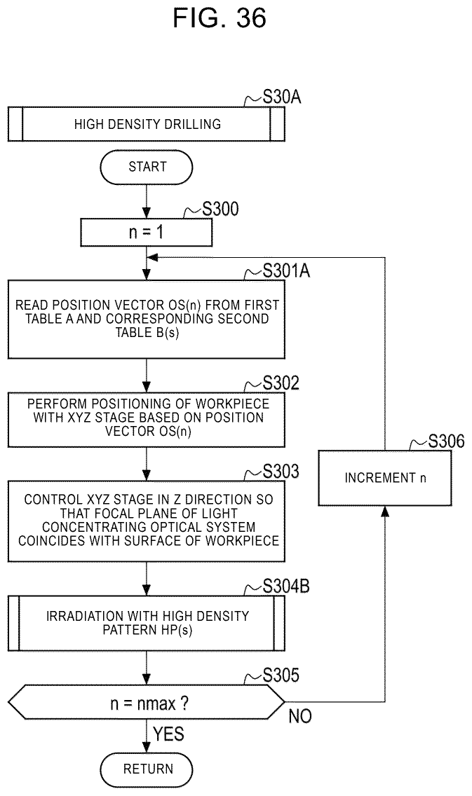

FIG. 36 shows details of the high density drilling process (step S30A) according to the first embodiment. Steps S301 and S304A of the first embodiment are replaced with steps S301A and S304B, respectively, and the rest of the processing is the same as the high density drilling process described with reference to FIG. 11. In the present embodiment, in step S301A, the laser processing processor 40 reads the position vector OS(n) from the first table A, and reads the second table B(s) corresponding to the position vector OS(n) defined in the first table A.

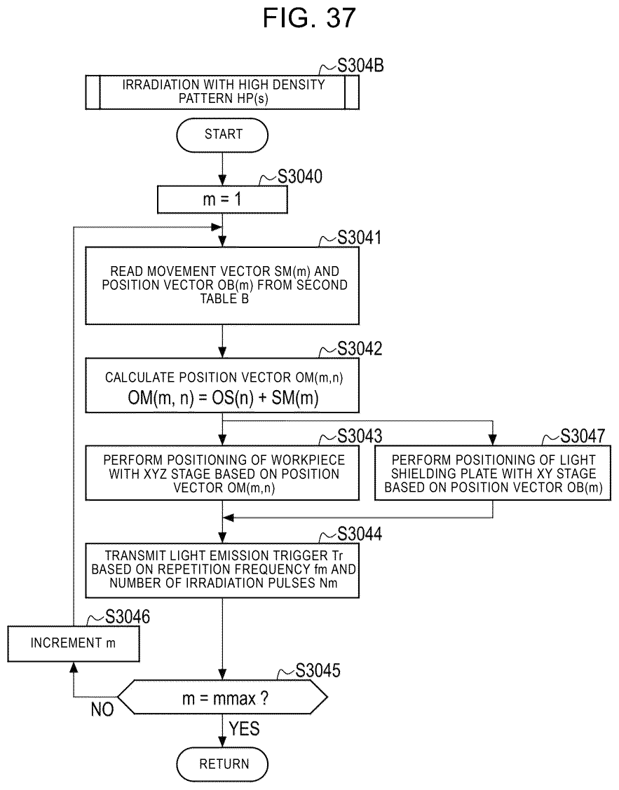

FIG. 37 shows details of the irradiation process (step S304B) with the high density pattern HP(s) according to the first embodiment. Only the content of step S3041 and addition of step S3047 are different from the irradiation process with the high density pattern HP described with reference to FIG. 12. In the present embodiment, in step S3041, the laser processing processor 40 reads the movement vector SM(m) and the position vector OB(m) from the second table B(s).

In the present embodiment, after calculating the position vector OM(m,n) in step S3042, the laser processing processor 40 executes step S3047 in parallel with step S3043 of positioning the workpiece 45 in the X direction and the Y direction. In step S3047, the laser processing processor 40 performs positioning of the light shielding plate 60 by controlling the XY stage 61 based on the position vector OB(m).

Then, after step S3043 and S3047 are completed, the laser processing processor 40 executes step S3044.

As described above, in the present embodiment, the laser processing processor 40 controls the XYZ stage 43 and the laser device 2 such that, in each of the plurality of step positions S(n) in the processing area 46 changed by controlling the XYZ stage 43, one of the high density patterns HP(1) to HP(4) is selected by controlling the XY stage 61 and irradiation is performed with the selected pattern. As a result, in the present embodiment, drilling is performed adequately in the first to fourth areas R1 to R4 at high density by the high density patterns HP(1) to HP(4), respectively.

### 3.3 Effect

In the laser processing apparatus 4a according to the present embodiment, even when the number of rows and the number of columns of the holes H included in the processing area 46 are not divisible by the number of rows and the number of columns of the high density pattern HP(1), respectively, the high density patterns HP(2) to HP(4) are generated by shielding a part of the multi-point pattern MP using the light shielding plate 60, so that drilling can be performed only in the processing area 46 at higher density.

It is conceivable to replace the DOE 50 to generate the high density pattern HP(1) to HP(4), but when the DOE 50 is replaced, it takes a long time to adjust the alignment, the fluence, and the like, and the throughput is reduced. In the present embodiment, the high density patterns HP(1) to HP(4) are generated by shielding a part of the multi-point pattern MP using the light shielding plate 60, so that high throughput can be maintained. Further, in the present embodiment, since the movement path is set to change the step position S(n) of the irradiation target to the adjacent step position S(n+1), the number of times of positioning of the light shielding plate 60 is reduced, and the throughput is further improved.

Here, in the present embodiment, each of the first to fourth areas R1 to R4 is a single block area, but one or more areas of the first to fourth areas R1 to R4 may be divided not being a block area.

Further, although the light shielding plate 60 has an L-shape in the present embodiment, the light shielding plate 60 may be any shape capable of shielding a desired number of rows and a desired number of columns of the multi-point pattern MP in the X direction and the Y direction from ends. For example, the light shielding plate 60 may have a shape having a rectangular opening having a size that allows the entire multi-point pattern MP to pass therethrough.

Further, in the present embodiment, the DOE 50 and the light concentrating optical system 51 generate the multi-point pattern MP, but the present invention is not limited thereto, and the DOE 50 may also have the function of the light concentrating optical system. In this case, the light concentrating optical system 51 can be omitted.

### 4. SECOND EMBODIMENT

A laser processing system 1b according to a second embodiment of the present disclosure will be described. Any component same as that described above is denoted by an identical reference sign, and duplicate description thereof is omitted unless specific description is needed.

### 4.1 Configuration

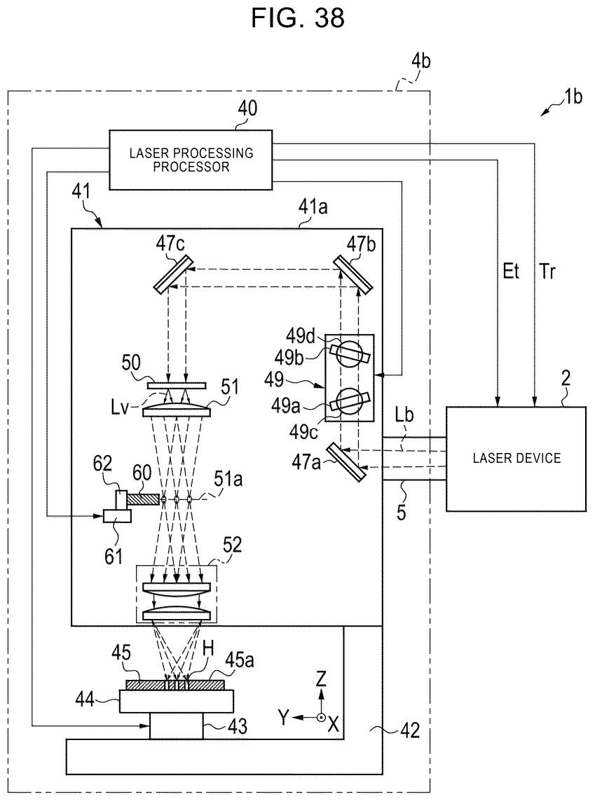

FIG. 38 schematically shows the configuration of the laser processing system 1b according to the second embodiment. The laser processing system 1b differs from the laser processing system 1a according to the first embodiment only in the configuration of a laser processing apparatus 4b. The laser processing apparatus 4b includes a transfer imaging optical system 52 in addition to the configuration of the laser processing apparatus 4a according to the first embodiment.

The transfer imaging optical system 52 is arranged on the optical path of the plurality of beams of the laser light Lv output from the light concentrating optical system 51. The transfer imaging optical system 52 is a reduced transfer imaging optical system that reduces the multi-point pattern MP formed on a focal plane 51a of the light concentrating optical system 51 and forms a transfer image thereof on the surface 45a of the workpiece 45.

In the present embodiment, the light shielding plate 60 is arranged on the focal plane 51a of the light concentrating optical system 51. The light shielding plate 60 is held by the holder 62 that is movable in the X direction and the Y direction on the XY stage 61. The XY stage 61 is fixed to the housing 41a and controlled by the laser processing processor 40.

Since the transfer imaging optical system 52 transfers and images an inverted image of the multi-point pattern MP on the surface 45a of the workpiece 45, the planar shape of the light shielding plate 60 according to the present embodiment is a shape obtained by reversing the planar shape of the light shielding plate 60 according to the first embodiment in the X direction and in the Y direction.

### 4.2 Operation

Operation of the laser processing system 1b according to the second embodiment is similar to the operation of the laser processing system 1a according to the first embodiment except that the movement direction for moving the light shielding plate 60 is opposite to that of the first embodiment.

In the present embodiment, the second table B(s) is a data table in which the movement vector SM(m) and the position vector OC(m) indicating the position of the light shielding plate 60 in the focal plane 51a are associated with the parameter m. For example, the position vector OC(m) is represented by an X coordinate Cxm and a Y coordinate Cym of the corner portion of the light shielding plate 60 in the focal plane 51a.

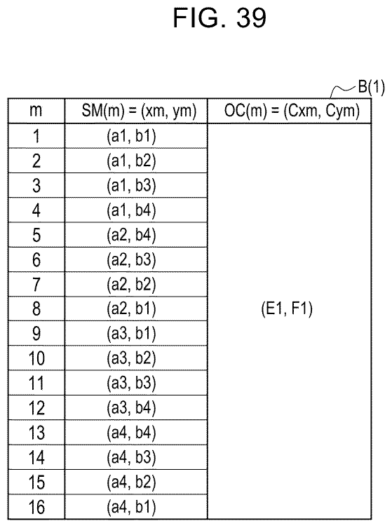

FIG. 39 shows an example of the second table B(1). In the second table B(1), in addition to the movement vector SM(m), the position vector OC(m) indicating the position of the light shielding plate 60 for generating the high density pattern HP(1) is associated with the parameter m. In the second table B(1), one position vector OC(m)=(E1,F1) is associated with 1≤m≤16.

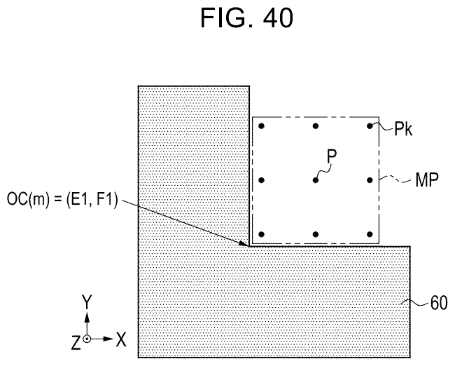

FIG. 40 shows an example of the position of the light shielding plate 60 associated with the second table B(1). In the example shown in FIG. 40, the light shielding plate 60 is located at a position where the multi-point pattern MP is not shielded in the focal plane 51a.

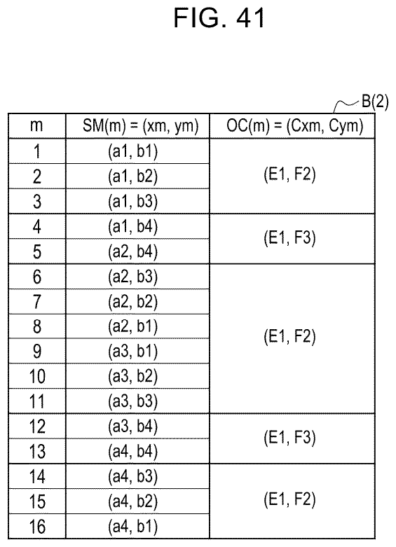

FIG. 41 shows an example of the second table B(2). In the second table B(2), in addition to the movement vector SM(m), the position vector OC(m) indicating the position of the light shielding plate 60 for generating the high density pattern HP(2) is associated with the parameter m. In the second table B(2), the position vector OC(m)=(E1,F2) is associated with 1≤m≤3, 6≤m≤11, and 14≤m≤16. Further, the position vector OC(m)=(E1,F3) is associated with 4≤m≤5 and 12≤m≤13.

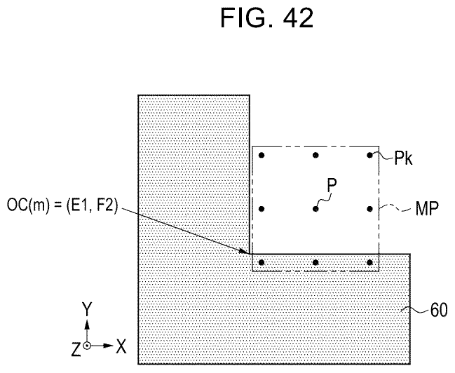

FIG. 42 shows an example of the position of the light shielding plate 60 associated with the second table B(2). In the example shown in FIG. 42, the light shielding plate 60 is located to shield one row of the multi-point pattern MP in the focal plane 51a based on the position vector OC(m)=(E1,F2).

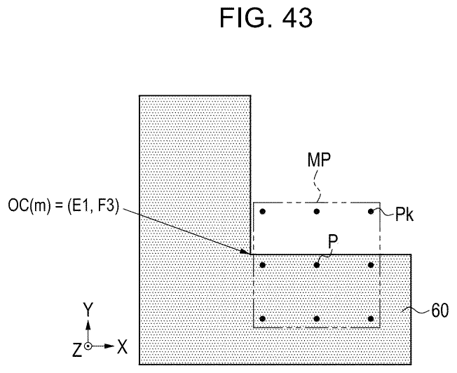

FIG. 43 shows an example of the position of the light shielding plate 60 associated with the second table B(2). In the example shown in FIG. 43, the light shielding plate 60 is located to shield two rows of the multi-point pattern MP in the focal plane 51a based on the position vector OC(m)=(E1,F3).

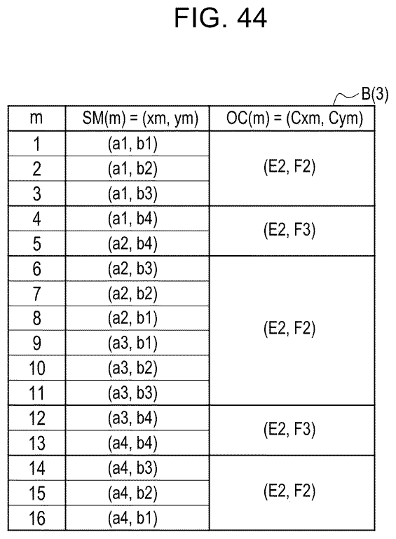

FIG. 44 shows an example of the second table B(3). In the second table B(3), in addition to the movement vector SM(m), the position vector OC(m) indicating the position of the light shielding plate 60 for generating the high density pattern HP(3) is associated with the parameter m. In the second table B(3), the position vector OC(m)=(E2,F2) is associated with 1≤m≤3, 6≤m≤11, and 14≤m≤16. Further, the position vector OC(m)=(E2,F3) is associated with 4≤m≤5 and 12≤m≤13.

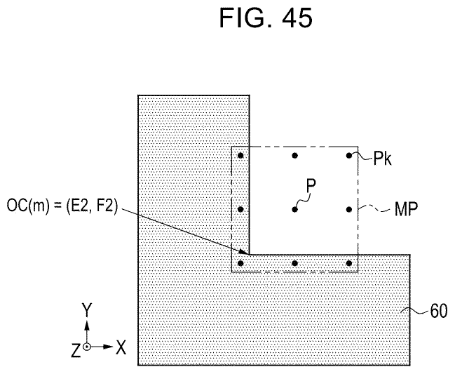

FIG. 45 shows an example of the position of the light shielding plate 60 associated with the second table B(3). In the example shown in FIG. 45, the light shielding plate 60 is located to shield one row and one column of the multi-point pattern MP in the focal plane 51a based on the position vector OC(m)=(E2,F2).

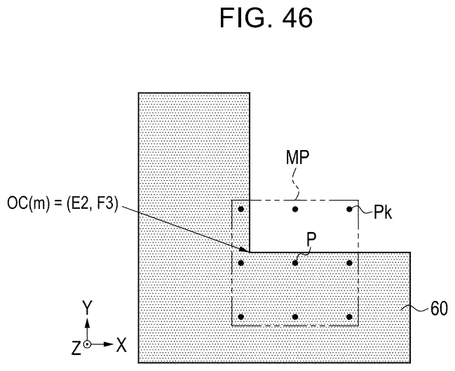

FIG. 46 shows an example of the position of the light shielding plate 60 associated with the second table B(3). In the example shown in FIG. 46, the light shielding plate 60 is located to shield two rows and one column of the multi-point pattern MP in the focal plane 51a based on the position vector OC(m)=(E2,F3).

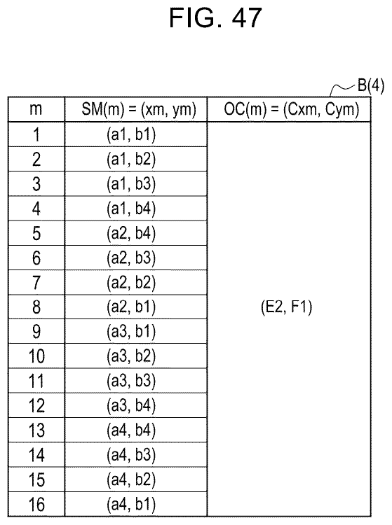

FIG. 47 shows an example of the second table B(4). In the second table B(4), in addition to the movement vector SM(m), the position vector OC(m) indicating the position of the light shielding plate 60 for generating the high density pattern HP(4) is associated with the parameter m. In the second table B(1), the position vector OC(m)=(E2,F1) is associated with 1≤m≤16.

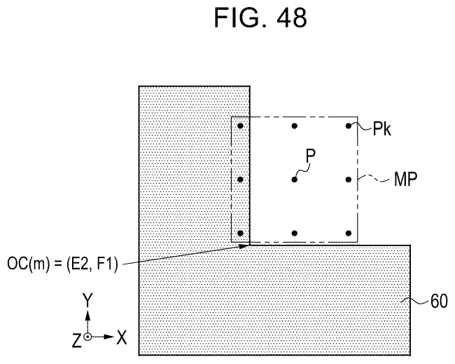

FIG. 48 shows an example of the position of the light shielding plate 60 associated with the second table B(4). In the example shown in FIG. 48, the light shielding plate 60 is located to shield one column of the multi-point pattern MP in the focal plane 51a based on the position vector OC(m)=(E2,F1).

### 4.3 Effect

For example, when the workpiece 45 is an alkali-free glass substrate, the target fluence Fm at the surface 45a of the workpiece 45 is required to be as high as several tens J/cm². Therefore, when the light shielding plate 60 is arranged in the vicinity of the surface 45a of the workpiece 45 as in the first embodiment, the light shielding plate 60 may be damaged. On the other hand, in the present embodiment, since the light shielding plate 60 is arranged on the focal plane 51a of the light concentrating optical system 51, the fluence of the light shielding plate 60 is lowered, and damage on the light shielding plate 60 is suppressed. Specifically, when the magnification of the transfer imaging optical system 52 is defined as 1/M, the fluence at the focal plane 51a is 1/M² times of the target fluence Fm at the surface 45a of the workpiece 45. Here, M>1 is satisfied.

Further, to suppress damage on the light shielding plate 60, it is preferable to use the light shielding plate 60 having a large thickness. However, when the pitch of the holes H to be formed in the workpiece 45 is small or the numerical aperture NA is large, it is difficult to arrange the light shielding plate 60 having a large thickness on the surface 45a of the workpiece 45. On the other hand, in the present embodiment, since the light shielding plate 60 is arranged on the focal plane 51a where the light concentration spots P are arranged at a pitch larger than the pitch of the holes H, the light shielding plate 60 having a larger thickness than that of the first embodiment can be used.

In the present embodiment, the transfer imaging optical system 52 is a reduced transfer imaging optical system, but the transfer imaging optical system 52 may be an equal magnification transfer imaging optical system that transfers and images the multi-point pattern MP formed on the focal plane 51a to the surface 45a of the workpiece 45 at an equal magnification. The present embodiment can also be modified in a similar manner as the first embodiment.

### 5. THIRD EMBODIMENT

A laser processing system 1c according to a third embodiment of the present disclosure will be described. Any component same as that described above is denoted by an identical reference sign, and duplicate description thereof is omitted unless specific description is needed.

### 5.1 Configuration

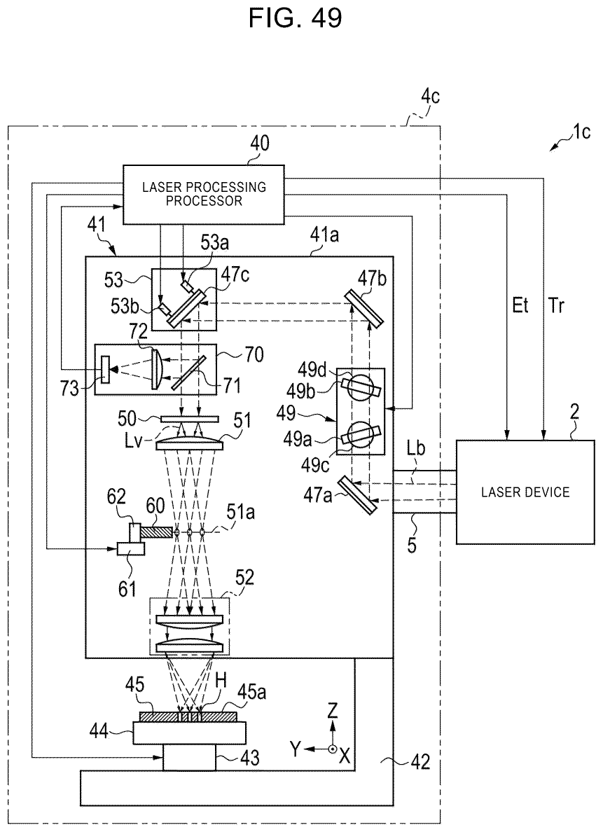

FIG. 49 schematically shows the configuration of the laser processing system 1c according to the third embodiment. The laser processing system 1c differs from the laser processing system 1b according to the second embodiment only in the configuration of a laser processing apparatus 4c. The laser processing apparatus 4c includes a beam steering device 53 and a pointing measurement device 70 in addition to the configuration of the laser processing apparatus 4b according to the second embodiment.

The beam steering device 53 includes two actuators 53a, 53b for changing the angle of the high reflection mirror 47c. The actuators 53a, 53b are controlled by the laser processing processor 40 to change the angle of the high reflection mirror 47c about two orthogonal axes.

The pointing measurement device 70 includes a beam splitter 71, a light concentrating lens 72, and a two-dimensional optical sensor 73. The beam splitter 71 is arranged on the optical path of the laser light Lb between the beam steering device 53 and the DOE 50. The beam splitter 71 reflects a part of the laser light Lb reflected by the high reflection mirror 47c and transmits the other part of the laser light Lb. The laser light Lb transmitted through the beam splitter 71 is incident on the DOE 50.

The light concentrating lens 72 is arranged on the optical path of the laser light Lb reflected by the beam splitter 71, and concentrates the laser light Lb. The two-dimensional optical sensor 73 is arranged at a position where the light concentrating lens 72 can detect the concentrated image generated on the focal plane. The two-dimensional optical sensor 73 may be a two-dimensional position sensitive detector (PSD) or a two-dimensional photodiode array. The two-dimensional optical sensor 73 measures the position of the concentrated image, that is, the pointing of the laser light Lb, and transmits the measurement value to the laser processing processor 40.

In the present embodiment, the laser processing processor 40 changes the incident angle of the laser light Lb incident on the DOE 50 by controlling the angle of the high reflection mirror 47c via the beam steering device 53. In response to the change of the incident angle of the laser light Lb incident on the DOE 50, the multi-point pattern MP moves within the focal plane 51a. That is, the beam steering device 53 is an example of the “second actuator” according to the technology of the present disclosure. The XYZ stage 43 is an example of the “third actuator” according to the technology of the present disclosure.

In the present embodiment, the laser processing processor 40 performs feedback control so that the position of the multi-point pattern MP with respect to the light shielding plate 60 becomes a target position based on the measurement value of the pointing transmitted from the pointing measurement device 70.

The planar shape of the light shielding plate 60 according to the present embodiment is similar to the planar shape of the light shielding plate 60 according to the second embodiment. In the present embodiment, the relative position of the light shielding plate 60 with respect to the multi-point pattern MP is changed by controlling the beam steering device 53 to move the multi-point pattern MP with the light shielding plate 60 fixed. In the present embodiment, it is possible to generate the high density pattern HP(s) by finely moving the multi-point pattern MP in the focal plane 51a in the X direction and the Y direction by a step-and-repeat method with the light shielding plate 60 fixed.

### 5.2 Operation

In the operation of the laser processing system 1c according to the third embodiment, the laser processing processor 40 finely moves the multi-point pattern MP by controlling the beam steering device 53 instead of the XYZ stage 43 in the irradiation process with a high density pattern. Other operation is similar to that of the laser processing system 1b according to the second embodiment. Hereinafter, the irradiation process with a high density pattern of the present embodiment will be described.

In the present embodiment, the laser processing processor 40 controls the beam steering device 53 to change the incident angle of the laser light Lb incident on the DOE 50 when the multi-point pattern MP is finely moved in the focal plane 51a. Further, the laser processing processor 40 calculates the incident angle of the laser light Lb incident on the DOE 50 based on the measurement value of the pointing transmitted from the pointing measurement device 70, and performs feedback control so that the incident angle becomes the target angle.

In the present embodiment, the second table B(s) is a data table in which a target angle Θ(m) and a position vector OC(s) indicating the position of the light shielding plate 60 in the focal plane 51a are associated with the parameter m. The target angle Θ(m) is an incident angle of the laser light Lb incident on the DOE 50 when the reference spot Pk is at the m-th position. For example, the position vector OC(s) is represented by an X coordinate Cxs and a Y coordinate Cys of the corner portion of the light shielding plate 60 in the focal plane 51a. The position vector OC(s) is an example of the “control value of the first actuator” according to the technology of the present disclosure. The target angle Θ(m) is an example of the “control value of the second actuator” according to the technology of the present disclosure.

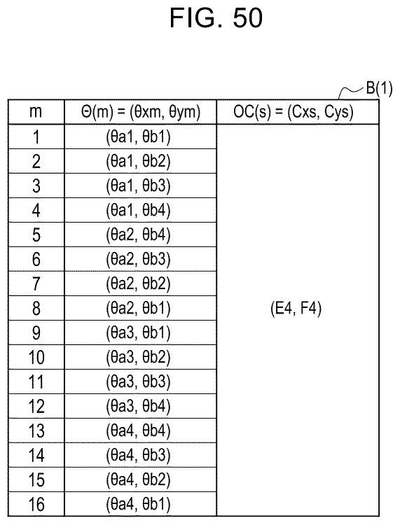

FIG. 50 shows an example of the second table B(1). In the second table B(1), in addition to the target angle Θ(m), the position vector OC(s) indicating the position of the light shielding plate 60 for generating the high density pattern HP(1) is associated with the parameter m. In the second table B(1), one position vector OC(s)=(E4,F4) is associated with 1≤m≤16.

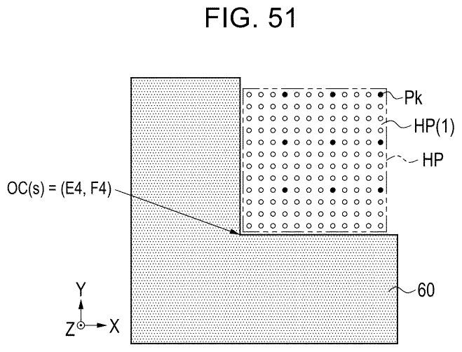

FIG. 51 shows an example of the position of the light shielding plate 60 associated with the second table B(1). In the example shown in FIG. 51, the light shielding plate 60 is located at a position where the high density pattern HP generated in the focal plane 51a is not shielded by controlling the beam steering device 53 to finely move the multi-point pattern MP. In the example shown in FIG. 51, since the high density pattern HP is not shielded by the light shielding plate 60, irradiation with the high density pattern HP(1) is performed on the surface 45a of the workpiece 45.

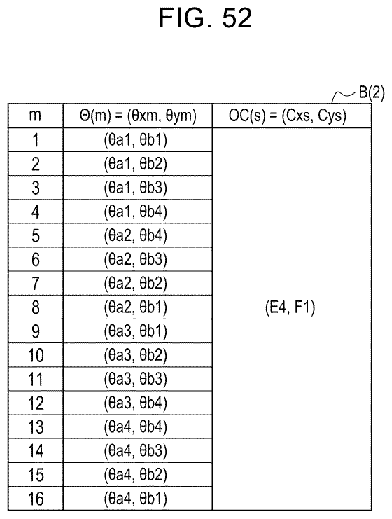

FIG. 52 shows an example of the second table B(2). In the second table B(2), in addition to the target angle Θ(m), the position vector OC(s) indicating the position of the light shielding plate 60 for generating the high density pattern HP(2) is associated with the parameter m. In the second table B(2), one position vector OC(s)=(E4,F1) is associated with 1≤m≤16.

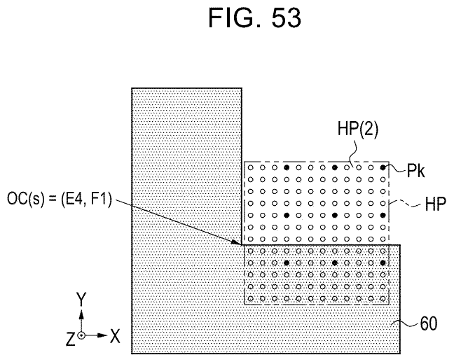

FIG. 53 shows an example of the position of the light shielding plate 60 associated with the second table B(2). In the example shown in FIG. 53, the light shielding plate 60 is located to shield five rows of the high density pattern HP. In the example shown in FIG. 53, five rows of the high density pattern HP are shielded by the light shielding plate 60, so that the high density pattern HP(2) is generated and irradiation therewith is performed on the surface 45a of the workpiece 45.

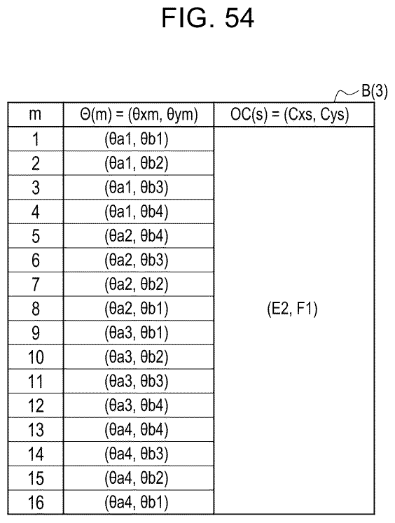

FIG. 54 shows an example of the second table B(3). In the second table B(3), in addition to the target angle Θ(m), the position vector OC(s) indicating the position of the light shielding plate 60 for generating the high density pattern HP(3) is associated with the parameter m. In the second table B(3), one position vector OC(s)=(E2,F1) is associated with 1≤m≤16.

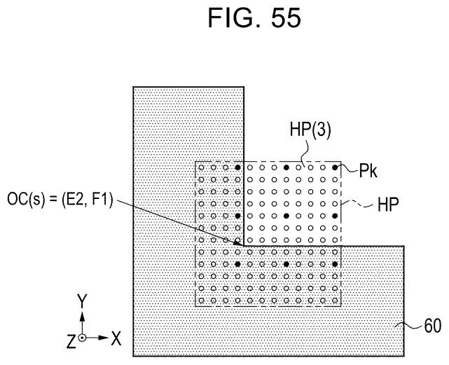

FIG. 55 shows an example of the position of the light shielding plate 60 associated with the second table B(3). In the example shown in FIG. 55, the light shielding plate 60 is located to shield five rows and four columns of the high density pattern HP. In the example shown in FIG. 55, five rows and four columns of the high density pattern HP are shielded by the light shielding plate 60, so that the high density pattern HP(3) is generated and irradiation thereof is performed on the surface 45a of the workpiece 45.

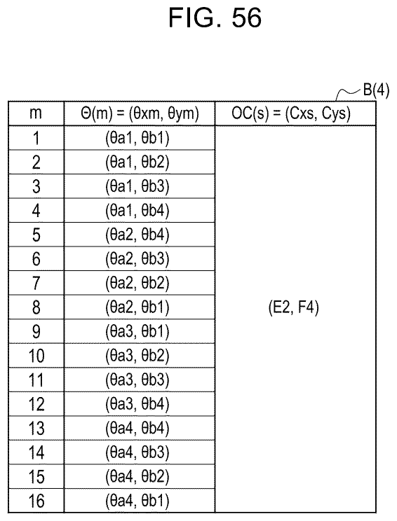

FIG. 56 shows an example of the second table B(4). In the second table B(4), in addition to the target angle Θ(m), the position vector OC(s) indicating the position of the light shielding plate 60 for generating the high density pattern HP(4) is associated with the parameter m. In the second table B(4), one position vector OC(s)=(E2,F4) is associated with 1≤m≤16.

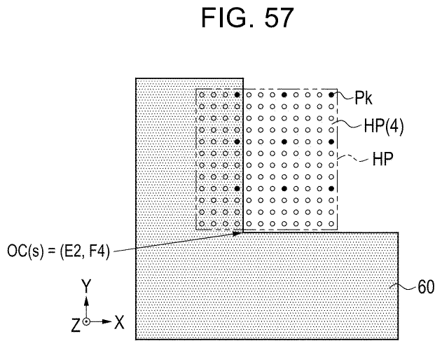

FIG. 57 shows an example of the position of the light shielding plate 60 associated with the second table B(4). In the example shown in FIG. 57, the light shielding plate 60 is located to shield four columns of the high density pattern HP. In the example shown in FIG. 57, four columns of the high density pattern HP are shielded by the light shielding plate 60, so that the high density pattern HP(4) is generated and irradiation therewith is performed on the surface 45a of the workpiece 45.

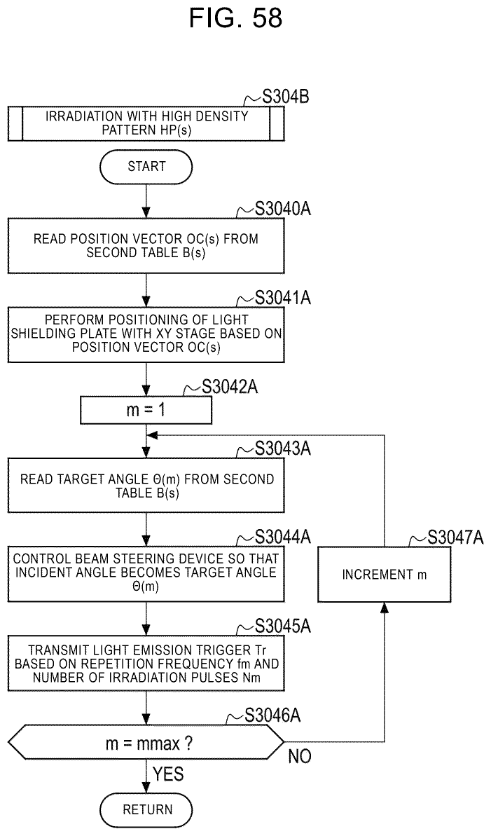

FIG. 58 shows details of the irradiation process (step S304B) with the high density pattern HP(s) according to the third embodiment. In step S304B according to the present embodiment, first, the laser processing processor 40 reads the position vector OC(s) from the second table B(s) (step S3040A). Next, the laser processing processor 40 controls the XY stage 61 based on the position vector OC(s) to perform positioning of the light shielding plate 60 (step S3041A).

The laser processing processor 40 sets the parameter m indicating the position of the reference spot Pk to 1 (step S3042A).

Next, the laser processing processor 40 reads the target angle Θ(m) from the second table B(s) (step S3043A). Then, the laser processing processor 40 controls the beam steering device 53 so that the incident angle of the laser light Lb incident on the DOE 50 becomes the target angle Θ(m) (step S3044A).

Next, the laser processing processor 40 transmits the light emission trigger Tr to the laser device 2 based on the repetition frequency fm and the number of irradiation pulses Nm (step S3045A). Accordingly, among the light concentration spots P included in the multi-point pattern MP, light having passed through the focal plane 51a without being shielded by the light shielding plate 60 is radiated to the surface 45a of the workpiece 45 via the transfer imaging optical system 52.

Next, the laser processing processor 40 determines whether or not the currently set parameter m is the maximum value mmax (step S3046A). When the parameter m is determined not to be the maximum value mmax (step S3046A: NO), the laser processing processor 40 increments the parameter m (step S3047A), and returns processing to step S3043A.

The laser processing processor 40 repeatedly executes steps S3043A to S3047A until the parameter m reaches the maximum value mmax. When the parameter m is determined to be the maximum value mmax (step S3046A: YES), the laser processing processor 40 ends the irradiation process with the high density pattern HP(s).

### 5.3 Effect

In the present embodiment, since the multi-point pattern MP is finely moved by the beam steering device 53 when the high density pattern HP(s) is generated, the light shielding plate 60 can be fixed without being required to be moved as in the second embodiment. Accordingly, the throughput is further improved.

Further, although the pointing measurement device 70 is not an essential component, movement and positioning of the multi-point pattern MP can be performed with high accuracy by performing feedback control using the pointing measurement device 70.

In the embodiments described above, the incident angle of the laser light Lb incident on the DOE 50 is changed by the beam steering device 53, but the incident angle of the laser light Lb may be changed by using an acoustic optical element. As the acoustic optical element, it is preferable to use an acoustic optical element of quartz that can also be used for ultraviolet rays, and to control the incident angle of the laser light Lb in two axis directions. The acoustic optical element is an example of the “second actuator” according to the technology of the present disclosure.

In the present embodiment, the transfer imaging optical system 52 is a reduced transfer imaging optical system, but the transfer imaging optical system 52 may be an equal magnification transfer imaging optical system that transfers and images the multi-point pattern MP formed on the focal plane 51a to the surface 45a of the workpiece 45 at an equal magnification.

Further, in the present embodiment, the multi-point pattern MP generated by the DOE 50 is transferred and imaged on the surface 45a of the workpiece 45 via the transfer imaging optical system 52, but the present invention is not limited thereto. As in the first embodiment, irradiation with the multi-point pattern MP generated by the DOE 50 may be performed on the surface 45a of the workpiece 45 via the light concentrating optical system 51, and the light shielding plate 60 may be arranged in the vicinity of the surface 45a.

The present embodiment can also be modified in a similar manner as the first embodiment.

### 6. ELECTRONIC DEVICE MANUFACTURING METHOD

The laser processing method according to each of the embodiments described above can be applied to forming a through hole in a glass substrate included in an interposer 102 in manufacturing an electronic device 100 described below.

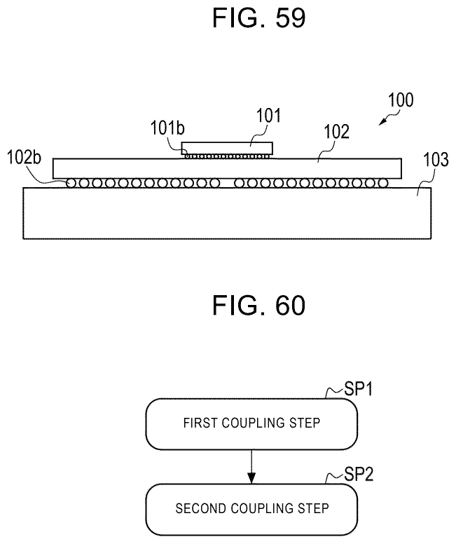

FIG. 59 schematically shows the configuration of the electronic device 100. The electronic device 100 shown in FIG. 59 includes an integrated circuit chip 101, the interposer 102, and a circuit substrate 103. The integrated circuit chip 101 is a chip-shaped integrated circuit substrate in which an integrated circuit is formed on, for example, a silicon substrate. The integrated circuit chip 101 is provided with a plurality of bumps 101b electrically connected to the integrated circuit.

The interposer 102 includes an insulating glass substrate in which a plurality of through holes are formed, and a conductor that electrically connects the front and back of the glass substrate is provided in each through hole. A plurality of lands connected to the bumps 101b provided on the integrated circuit chip 101 are formed on one surface of the interposer 102, and each land is electrically connected to one of the conductors in the through holes. A plurality of bumps 102b are provided on the other surface of the interposer 102, and each bump 102b is electrically connected to one of the conductors in the through holes.

A plurality of lands connected to the respective bumps 102b are formed on one surface of the circuit substrate 103. The circuit substrate 103 includes a plurality of terminals electrically connected to the lands.

FIG. 60 shows a manufacturing method of the electronic device 100. As shown in FIG. 60, the manufacturing method of the electronic device 100 in the present description includes a first coupling step SP1 and a second coupling step SP2. In the first coupling step SP1, the integrated circuit chip 101 and the interposer 102 are coupled. Specifically, each bump 101b of the integrated circuit chip 101 is arranged on a corresponding land of the interposer 102 to electrically connect the bumps 101b and the lands. Thus, the integrated circuit chip 101 and the interposer 102 are electrically connected to each other.

In the second coupling step SP2, the interposer 102 and the circuit substrate 103 are coupled. Specifically, each bump 102b of the interposer 102 is arranged on a corresponding land of the circuit substrate 103 to electrically connect the bumps 102b and the lands. Thus, the integrated circuit chip 101 is electrically connected to the circuit substrate 103 via the interposer 102. Through the above steps, the electronic device 100 is manufactured.

### 7. CONFIGURATION EXAMPLE OF LASER PROCESSING PROCESSOR

In the present disclosure, the laser processing processor 40 is configured by, for example, a central processing unit (CPU). The laser processing processor 40 executes various types of processing described above based on a program stored in the memory. Some or all of the functions of the laser processing processor 40 may be realized by using an integrated circuit such as a field programmable gate array (FPGA) or an application specific integrated circuit (ASIC).

The description above is intended to be illustrative and the present disclosure is not limited thereto. Therefore, it would be obvious to those skilled in the art that various modifications to the embodiments of the present disclosure would be possible without departing from the spirit and the scope of the appended claims.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of the any thereof and any other than A, B, and C.

What is claimed is:

1. A laser processing apparatus comprising:
a diffractive optical element configured to divide first laser light output from a laser device into a plurality of beams of second laser light and output the second laser light;
a light concentrating optical system configured to generate a grid-like multi-point pattern in which a plurality of light concentration spots are arranged in a row direction and a column direction by concentrating the plurality of beams of second laser light;
a light shielding plate capable of shielding at least a part of the multi-point pattern;
a first actuator configured to move the light shielding plate in a direction perpendicular to an optical axis of the light concentrating optical system;
a second actuator capable of generating high density patterns densified by moving the multi-point pattern at a movement pitch shorter than a grid interval of the multi-point pattern;
a third actuator configured to move a workpiece in the direction perpendicular to the optical axis; and
a laser processing processor configured to, at each of step positions in a processing area changed by controlling the third actuator, select one of the high density patterns being at least four patterns, each having a different number of rows or a different number of columns, and control the second actuator and the laser device to perform irradiation with the selected pattern, so that drilling is performed on a surface of the workpiece only in the processing area where drilling is required.

2. The laser processing apparatus according to claim 1,
wherein the laser processing processor determines at least four areas which are irradiated with the at least four high density patterns respectively so that drilling is performed only in the processing area.

3. The laser processing apparatus according to claim 2,
wherein each of the at least four areas is a single block area.

4. The laser processing apparatus according to claim 2,
wherein the laser processing processor controls the third actuator to change the step position of an irradiation target to the step position adjacent thereto.

5. The laser processing apparatus according to claim 1,
wherein the first actuator is a two-axis movement stage.

6. The laser processing apparatus according to claim 1,
wherein the second actuator and the third actuator are movement stages that move the workpiece in the direction perpendicular to the optical axis.

7. The laser processing apparatus according to claim 1,
wherein the second actuator is a beam steering device that changes an incident angle of the first laser light incident on the diffractive optical element, and
the third actuator is a movement stage that moves the workpiece in the direction perpendicular to the optical axis.

8. The laser processing apparatus according to claim 7,
further comprising a pointing measurement device arranged on an optical path of the first laser light between the beam steering device and the diffractive optical element, and configured to measure a pointing of the first laser light.

9. The laser processing apparatus according to claim 8,
wherein the laser processing processor performs feedback control on the incident angle of the first laser light incident on the diffractive optical element based on a measurement value of the pointing by the pointing measurement device.

10. The laser processing apparatus according to claim 1,
wherein the workpiece is arranged such that the surface coincides with a focal plane of the light concentrating optical system.

11. The laser processing apparatus according to claim 1,
further comprising a transfer imaging optical system that forms a transfer image of the multi-point pattern generated by the light concentrating optical system on the surface.

12. The laser processing apparatus according to claim 11,
wherein the transfer imaging optical system is a reduced transfer imaging optical system that reduces the multi-point pattern and forms a transfer image thereof on the surface.

13. The laser processing apparatus according to claim 12,
wherein the light shielding plate is arranged on a focal plane of the light concentrating optical system.

14. The laser processing apparatus according to claim 13,
wherein the first actuator is a two-axis movement stage,
the second actuator is a beam steering device that changes an incident angle of the first laser light incident on the diffractive optical element, and
the third actuator is a movement stage that moves the workpiece in the direction perpendicular to the optical axis.

15. The laser processing apparatus according to claim 1,
wherein the laser processing processor controls the first actuator and the second actuator based on a data table in which a relationship between a control value of the first actuator and a control value of the second actuator for generating the at least four high density patterns is defined.

16. A control method of a laser processing apparatus, comprising:
at each of step positions in a processing area changed by controlling a third actuator, selecting one of high density patterns being at least four patterns, each having a different number of rows or a different number of columns, and controlling a second actuator and a laser device to perform irradiation with the selected pattern, so that drilling is performed on a surface of a workpiece only in the processing area where drilling is required,
the selecting and the controlling being performed by a laser processing processor, and
the laser processing apparatus including:
a diffractive optical element configured to divide first laser light output from the laser device into a plurality of beams of second laser light and output the second laser light;
a light concentrating optical system configured to generate a grid-like multi-point pattern in which a plurality of light concentration spots are arranged in a row direction and a column direction by concentrating the plurality of beams of second laser light;
a light shielding plate capable of shielding at least a part of the multi-point pattern;
a first actuator configured to move the light shielding plate in a direction perpendicular to an optical axis of the light concentrating optical system;
the second actuator capable of generating the high density patterns densified by moving the multi-point pattern at a movement pitch shorter than a grid interval of the multi-point pattern; and
the third actuator configured to move the workpiece in the direction perpendicular to the optical axis.

17. An electronic device manufacturing method, comprising:
forming a plurality of through holes in a glass substrate as a workpiece with a laser processing apparatus;
coupling and electrically connecting an interposer and an integrated circuit chip to each other, the interposer including the glass substrate and a conductor arranged in each of the plurality of through holes; and
coupling and electrically connecting the interposer and a circuit substrate to each other,
the laser processing apparatus including:
a diffractive optical element configured to divide first laser light output from a laser device into a plurality of beams of second laser light and output the second laser light;
a light concentrating optical system configured to generate a grid-like multi-point pattern in which a plurality of light concentration spots are arranged in a row direction and a column direction by concentrating the plurality of beams of second laser light;
a light shielding plate capable of shielding at least a part of the multi-point pattern;
a first actuator configured to move the light shielding plate in a direction perpendicular to an optical axis of the light concentrating optical system;
a second actuator capable of generating high density patterns densified by moving the multi-point pattern at a movement pitch shorter than a grid interval of the multi-point pattern;
a third actuator configured to move a workpiece in the direction perpendicular to the optical axis; and
a laser processing processor configured to, at each of step positions in a processing area changed by controlling the third actuator, select one of the high density patterns being at least four patterns, each having a different number of rows or a different number of columns, and control the second actuator and the laser device to perform irradiation with the selected pattern, so that drilling is performed on a surface of the workpiece only in the processing area where drilling is required.
